(19) United States
(12) Patent Application Publication
(10) Pub. No.: US 2014/0124906 A1
(43) Pub. Date: May 8, 2014

(54) SEMICONDUCTOR PACKAGE AND METHOD OF MANUFACTURING THE SAME

(71) Applicants: Soo-Jeoung Park, Hwaseong-si (KR); Hee-Seok Lee, Yongin-si (KR)

(72) Inventors: Soo-Jeoung Park, Hwaseong-si (KR); Hee-Seok Lee, Yongin-si (KR)

(21) Appl. No.: 13/947,417

(22) Filed: Jul. 22, 2013

(30) Foreign Application Priority Data
Nov. 5, 2012 (KR) 10-2012-0124401

(51) Int. Cl. H01L 23/552; H01L 21/56

(52) U.S. Cl. CPC H01L 23/552; H01L 21/56
USPC 257/659; 438/127

(57) ABSTRACT

A semiconductor package includes a mounting substrate having a chip-mounting region and a peripheral region. A first semiconductor chip is mounted on the chip-mounting region of the mounting substrate. A first molding member covers at least a portion of the first semiconductor chip on the mounting substrate. A plurality of first conductive connection members penetrate through at least a portion of the first molding member to protrude from the first molding member. The first conductive connection members are electrically connected to a plurality of ground connection pads provided on the peripheral region of the mounting substrate, respectively. An electromagnetic interference (EMI) shield member is disposed on an upper surface of the first molding member to cover the first semiconductor chip. The EMI shield member is supported by the first conductive molding members and spaced apart from the first molding member.

### CROSS-REFERENCE TO RELATED APPLICATION

This application claims priority under 35 USC §119 to Korean Patent Application No. 10-2012-0124401, filed on Nov. 5, 2012 in the Korean Intellectual Property Office (KIPO), the contents of which are herein incorporated by reference in their entirety.

### BACKGROUND

1. Field

Exemplary embodiments in accordance with principles of inventive concepts relate to a semiconductor package and a method of manufacturing a semiconductor package. More particularly, exemplary embodiments in accordance with principles of inventive concepts relate to a semiconductor package including a semiconductor chip and a method of manufacturing the semiconductor package.

2. Description of the Related Art

Electromagnetic waves emitted from a semiconductor package may generate noise and interference with devices within range of the emissions and may cause those devices to malfunction or otherwise create errors. Electromagnetic interference (EMI) shields may be installed to prevent such interference. However, conventional shielding, such as the use of a radiation plate that covers at least one surface of an electronic device, may add to the thickness of the final semiconductor package and degrade or limit the EMI shielding performance.

### SUMMARY

Exemplary embodiments in accordance with principles of inventive concepts provide a semiconductor package having an EMI shield structure capable of having a thin thickness and preventing a warpage thereof.

In exemplary embodiments in accordance with principles of inventive concepts, a semiconductor package includes: a mounting substrate having a chip-mounting region and a peripheral region; a first semiconductor chip mounted on the chip-mounting region of the mounting substrate; a first molding member covering at least a portion of the first semiconductor chip on the mounting substrate; a plurality of first conductive connection members penetrating through at least a portion of the first molding member to protrude from the first molding member, the first conductive connection members electrically connected to a plurality of ground connection pads provided on the peripheral region of the mounting substrate, respectively; and an electromagnetic interference (EMI) shield member disposed on an upper surface of the first molding member to cover the first semiconductor chip, the EMI shield member supported by the first conductive connection members and spaced apart from the first molding member.

In exemplary embodiments in accordance with principles of inventive concepts, a semiconductor package includes a first molding member that leaves exposed an upper surface of the first semiconductor chip.

In exemplary embodiments in accordance with principles of inventive concepts, an EMI shield member is adhered to the exposed upper surface of the first semiconductor chip by a thermally conductive adhesive layer.

In exemplary embodiments in accordance with principles of inventive concepts, an EMI shield member comprises a thermal interface material (TIM).

In exemplary embodiments in accordance with principles of inventive concepts, a first semiconductor chip is electrically connected to the mounting substrate by a plurality of bumps.

In exemplary embodiments in accordance with principles of inventive concepts, first conductive connection member comprises a solder ball, and the solder ball is arranged on the ground connection pad.

In exemplary embodiments in accordance with principles of inventive concepts, first conductive connection member comprises a conductive material, through-holes are formed through the first molding member to leave exposed the ground connection pads, and the conductive material fills the through-holes.

In exemplary embodiments in accordance with principles of inventive concepts, an EMI shield member comprises a graphite film or a copper film.

In exemplary embodiments in accordance with principles of inventive concepts, an EMI shield member covers at least a portion of an outer surface of the mounting substrate.

In exemplary embodiments in accordance with principles of inventive concepts a semiconductor package includes a second semiconductor package having a second semiconductor chip mounted thereon, the first semiconductor package having a first semiconductor chip stacked on the second semiconductor package, and a mounting substrate of the second semiconductor package includes a redistribution wiring substrate.

In exemplary embodiments in accordance with principles of inventive concepts, a method of manufacturing a semiconductor package includes: preparing a mounting substrate having a chip-mounting region and a peripheral region; disposing a first semiconductor chip on the chip-mounting region of the mounting substrate; forming a first molding member covering at least a portion of the first semiconductor chip on the mounting substrate and having first conductive connection members, the first conductive connection members penetrating through at least a portion of the first molding member to protrude from the first molding member and electrically connected to a plurality of ground connection pads formed on the peripheral region of the mounting substrate, respectively; and disposing an EMI shield member on an upper surface of the first molding member to cover the first semiconductor chip, the EMI shield member supported by the first conductive connection members and spaced apart from the first molding member.

In exemplary embodiments in accordance with principles of inventive concepts, forming a first molding member includes: arranging solder balls on the ground connection pads formed on the peripheral region of the mounting substrate, respectively; and forming the first molding member to cover at least a portion of the first semiconductor chip on the mounting substrate and to leave exposed end portions of the solder balls.

In exemplary embodiments in accordance with principles of inventive concepts, forming a first molding member includes: forming a first preliminary molding member to cover at least a portion of the first semiconductor chip on the mounting substrate; forming through-holes in the first preliminary molding member to leave exposed the ground connection pads formed on the peripheral region of the mounting substrate; and filling the through-holes with a conductive material.

In exemplary embodiments in accordance with principles of inventive concepts, a first molding member is formed to leave exposed an upper surface of the first semiconductor chip.

In exemplary embodiments in accordance with principles of inventive concepts, an EMI shield member is adhered to the exposed upper surface of the first semiconductor chip by a thermally conductive adhesive layer.

In exemplary embodiments in accordance with principles of inventive concepts, an electronic memory package includes: a mounting substrate having a chip-mounting region and a peripheral region; a first memory chip mounted on the chip-mounting region; a first molding member covering at least a portion of the first memory chip on the mounting substrate; a plurality of first conductive connection members penetrating through at least a portion of the first molding member to protrude from the first molding member, the first conductive connection members electrically connected to a plurality of ground connection pads provided on the peripheral region of the mounting substrate; and an electromagnetic interference (EMI) shield member disposed on an upper surface of the first molding member to cover the first memory chip, the EMI shield member supported by the first conductive connection members and spaced apart from the first molding member.

In exemplary embodiments in accordance with principles of inventive concepts, an electronic memory package includes a second memory package having a second semiconductor chip mounted thereon, the first memory package having a first semiconductor chip stacked on the second memory package, and a mounting substrate of the second memory package includes a redistribution wiring substrate.

In exemplary embodiments in accordance with principles of inventive concepts, an electronic memory package includes an EMI shield member that includes graphite or copper.

In exemplary embodiments in accordance with principles of inventive concepts, an electronic memory system including a memory controller and a memory package that includes a mounting substrate having a chip-mounting region and a peripheral region; a first memory chip mounted on the chip-mounting region; a first molding member covering at least a portion of the first memory chip on the mounting substrate; a plurality of first conductive connection members penetrating through at least a portion of the first molding member to protrude from the first molding member, the first conductive connection members electrically connected to a plurality of ground connection pads provided on the peripheral region of the mounting substrate; and an electromagnetic interference (EMI) shield member disposed on an upper surface of the first molding member to cover the first memory chip, the EMI shield member supported by the first conductive connection members and spaced apart from the first molding member.

In accordance with principles of inventive concepts, a wireless electronic device includes an electronic memory system that includes a mounting substrate having a chip-mounting region and a peripheral region; a first memory chip mounted on the chip-mounting region; a first molding member covering at least a portion of the first memory chip on the mounting substrate; a plurality of first conductive connection members penetrating through at least a portion of the first molding member to protrude from the first molding member, the first conductive connection members electrically connected to a plurality of ground connection pads provided on the peripheral region of the mounting substrate; and an electromagnetic interference (EMI) shield member disposed on an upper surface of the first molding member to cover the first memory chip, the EMI shield member supported by the first conductive connection members and spaced apart from the first molding member.

Exemplary embodiments in accordance with principles of inventive concepts provide a method of manufacturing the semiconductor package.

According to exemplary embodiments in accordance with principles of inventive concepts, a semiconductor package includes a mounting substrate having a chip-mounting region and a peripheral region, a first semiconductor chip mounted on the chip-mounting region of the mounting substrate, a first molding member covering at least a portion of the first semiconductor chip on the mounting substrate, a plurality of first conductive connection members penetrating through at least a portion of the first molding member to protrude from the first molding member, the first conductive connection members electrically connected to a plurality of ground connection pads provided on the peripheral region of the mounting substrate, respectively, and an electromagnetic interference (EMI) shield member disposed on an upper surface of the first molding member to cover the first semiconductor chip, the EMI shield member supported by the first conductive molding members and spaced apart from the first molding member.

In exemplary embodiments in accordance with principles of inventive concepts, the first molding member may expose an upper surface of the first semiconductor chip.

In exemplary embodiments in accordance with principles of inventive concepts, the EMI shield member may be adhered to the exposed upper surface of the first semiconductor chip by a thermally conductive adhesive layer.

In exemplary embodiments in accordance with principles of inventive concepts, the EMI shield member may include a thermal interface material (TIM).

In exemplary embodiments in accordance with principles of inventive concepts, the first semiconductor chip may be electrically connected to the mounting substrate via a plurality of bumps.

In exemplary embodiments in accordance with principles of inventive concepts, the first conductive connection member may include a solder ball, and the solder ball may be arranged on the ground connection pad.

In exemplary embodiments in accordance with principles of inventive concepts, the first conductive connection member may include a conductive material, through-holes may be formed through the first molding member to leave exposed the ground connection pads, and the conductive material may fill the through-holes.

In exemplary embodiments in accordance with principles of inventive concepts, the EMI shield member may include a graphite film or a copper film.

In exemplary embodiments in accordance with principles of inventive concepts, the EMI shield member may cover at least a portion of an outer surface of the mounting substrate.

In exemplary embodiments in accordance with principles of inventive concepts, the semiconductor package may further include a second semiconductor package having a second semiconductor chip mounted thereon, the first semiconductor package having a first semiconductor chip may be stacked on the second semiconductor package, and a mounting substrate of the second semiconductor package may be a redistribution wiring substrate.

According to exemplary embodiments in accordance with principles of inventive concepts, in a method of manufacturing a semiconductor package, a mounting substrate having a chip-mounting region and a peripheral region is prepared. A first semiconductor chip is disposed on the chip-mounting region of the mounting substrate. A first molding member covering at least a portion of the first semiconductor chip and having first conductive connection members is formed on the mounting substrate. The first conductive connection members penetrate through at least a portion of the first molding member to protrude from the first molding member and are electrically connected to a plurality of ground connection pads formed on the peripheral region of the mounting substrate, respectively. An EMI shield member is disposed on an upper surface of the first molding member to cover the first semiconductor chip. The EMI shield member is supported by the first conductive molding members and spaced apart from the first molding member.

In exemplary embodiments in accordance with principles of inventive concepts, forming the first molding member may include arranging solder balls on the ground connection pads formed on the peripheral region of the mounting substrate, respectively, and forming the first molding member to cover at least a portion of the first semiconductor chip on the mounting substrate and to leave exposed end portions of the solder balls.

In exemplary embodiments in accordance with principles of inventive concepts, forming the first molding member may include forming a first preliminary molding member to cover at least a portion of the first semiconductor chip on the mounting substrate, forming through-holes in the first preliminary molding member to leave exposed the ground connection pads formed on the peripheral region of the mounting substrate, and filling the through-holes with a conductive material.

In exemplary embodiments in accordance with principles of inventive concepts, the first molding member may be formed to leave exposed an upper surface of the first semiconductor chip.

In exemplary embodiments in accordance with principles of inventive concepts, the EMI shield member may be adhered to the exposed upper surface of the first semiconductor chip by a thermally conductive adhesive layer.

According to exemplary embodiments in accordance with principles of inventive concepts, a semiconductor package may include an EMI shield member to cover a semiconductor chip. A molding member may be formed on a mounting substrate to leave exposed an upper surface of the semiconductor chip. Conductive connection members may protrude from the molding member. The conductive connection members may contact and support the EMI shield member to be spaced apart from the molding member.

Accordingly, a thickness of the semiconductor package may be reduced and an EMI shielding performance and a heat release performance may be enhanced. Additionally, the EMI shield member may be provided over the molding member of the semiconductor package having a thin thickness and be spaced apart from the molding member such that the warpage of the semiconductor package may be prevented.

### BRIEF DESCRIPTION OF THE DRAWINGS

Exemplary embodiments in accordance with principles of inventive concepts will be more clearly understood from the following detailed description taken in conjunction with the accompanying drawings. FIGS. 1 to 32 represent non-limiting, exemplary embodiments in accordance with principles of inventive concepts as described herein.

FIG. 1 is a cross-sectional view illustrating an exemplary embodiment of a semiconductor package in accordance with principles of inventive concepts.

FIGS. 2 to 6 are cross-sectional views illustrating the method of manufacturing the semiconductor package.

FIG. 7 is a cross-sectional view illustrating an exemplary embodiment of a semiconductor package in accordance with principles of inventive concepts.

FIGS. 8 to 11 are cross-sectional views illustrating the method of manufacturing the semiconductor package in accordance with principles of inventive concepts.

FIG. 12 is a cross-sectional view illustrating an exemplary embodiment of a semiconductor package in accordance with principles of inventive concepts.

FIG. 13 is a cross-sectional view illustrating an exemplary embodiment of a semiconductor package in accordance with principles of inventive concepts.

FIG. 14 is a plan view illustrating an EMI shield member of the semiconductor package in FIG. 13.

FIG. 15 is a cross-sectional view illustrating an exemplary embodiment of a semiconductor package in accordance with principles of inventive concepts.

FIGS. 16 to 18 are cross-sectional views illustrating a method of manufacturing an exemplary embodiment of a semiconductor package in accordance with principles of inventive concepts.

FIG. 19 is a cross-sectional view illustrating an exemplary embodiment of a semiconductor package in accordance with principles of inventive concepts.

FIGS. 20 to 22 are cross-sectional views illustrating the method of manufacturing the semiconductor package in accordance with principles of inventive concepts.

FIG. 23 is a cross-sectional view illustrating an exemplary embodiment of a semiconductor package in accordance with principles of inventive concepts.

FIGS. 24 to 25 are cross-sectional views illustrating the method of manufacturing the semiconductor package in accordance with principles of inventive concepts.

FIG. 26 is a cross-sectional view illustrating an exemplary embodiment of a semiconductor package in accordance with principles of inventive concepts.

FIG. 27 is a plan view illustrating an adhesive layer interposed between a molding member and an EMI shielding member of FIG. 26.

FIG. 28 is a plan view illustrating a second adhesive layer in accordance with one example embodiment.

FIG. 29 is a cross-sectional view illustrating an exemplary embodiment of a semiconductor package in accordance with principles of inventive concepts.

FIG. 30 illustrates another embodiment.

FIG. 31 illustrates still another embodiment.

FIG. 32 illustrates yet another embodiment.

### DESCRIPTION

Various exemplary embodiments will be described more fully hereinafter with reference to the accompanying drawings, in which exemplary embodiments are shown. Exemplary embodiments may, however, be embodied in many different forms and should not be construed as limited to exemplary embodiments set forth herein. Rather, these exemplary embodiments are provided so that this disclosure will be thorough, and will convey the scope of exemplary embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. The term “or” is used in an inclusive sense unless otherwise indicated.

It will be understood that, although the terms first, second, third, for example. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments in accordance with principles of inventive concepts will be explained in detail with reference to the accompanying drawings.

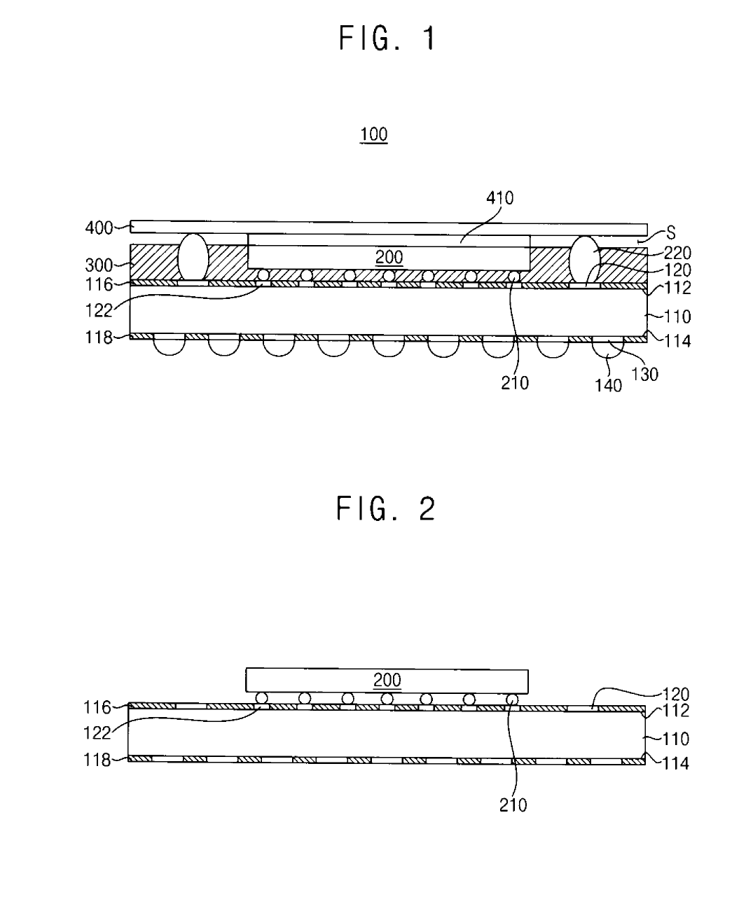

FIG. 1 is a cross-sectional view illustrating an exemplary embodiment of a semiconductor package in accordance with principles of inventive concepts. Semiconductor package 100 in accordance with principles of inventive concepts may include a mounting substrate 110, a first semiconductor chip 200 mounted on the mounting substrate 110, a first molding member 300 covering at least a portion of the first semiconductor chip 200, first conductive connection members 220 penetrating through at least a portion of the first molding member 300 and spaced apart from the first semiconductor chip 200, and an electromagnetic interference (EMI) shield member 400 covering the first semiconductor chip 200.

In exemplary embodiments in accordance with principles of inventive concepts, the mounting substrate 110 may have an upper surface 112 and a lower surface 114 facing each other. For example, the mounting substrate 110 may be a printed circuit board (PCB), which may be a multi-layered circuit board having various circuits and vias therein.

The mounting substrate 110 may have a chip-mounting region and a peripheral region. The first semiconductor chip 200 may be mounted on the upper surface 112 of the mounting substrate 110 and may be arranged in the chip-mounting region.

First bonding pads 122 for electrical connection with the first semiconductor chip 200 may be formed on the upper surface 112 of the mounting substrate 110. First ground connection pads 120 may be arranged in the peripheral region around the chip-mounting region.

Outer connection pads 130 for electrical connection with the semiconductor chip 200 may be formed on the lower surface 114 of the mounting substrate 110. The first bonding pads 122, the first ground connection pads 120 may be exposed by an insulation layer pattern 116 on the upper surface 112 of the mounting substrate 110, for example. The outer connection pads 130 may be exposed by an insulation layer pattern 118 on the lower surface 114 of the mounting substrate 110. The insulation layer patterns 116 and 118 may include silicon oxide, silicon nitride, or silicon oxynitride, for example.

The first bonding pads 122 and the first ground connection pads 120 may be electrically connected to each other by inner wirings of the mounting substrate 110.

Outer connection members 140 for electrical connection with an external device may be arranged on the outer connection pads 130 of the mounting substrate 110, respectively and may include a solder ball, for example.

In exemplary embodiments in accordance with principles of inventive concepts, the first semiconductor chip 200 may be mounted on the mounting substrate 110 such that an active surface thereof faces the mounting substrate 110. First semiconductor chip 200 may be mounted on the mounting substrate 110 by a flip-chip bonding method, for example. The first semiconductor chip 200 may be electrically connected to the mounting substrate 110 by bumps 210, which may be solder bumps, for example.

A plurality of the bumps 210 may be arranged on a plurality of the first bonding pads 122, respectively, such that the first semiconductor chip 200 and the mounting substrate 110 may be adhered to each other by the bumps 210. When the first semiconductor chip 200 is adhered to the mounting substrate 110, an adhesive may be underfilled between the first semiconductor chip 200 and the mounting substrate 110. The adhesive may include an epoxy material to reinforce a gap therebetween, for example.

In an exemplary embodiment in accordance with principles of inventive concepts, the first conductive connection members 220 may be arranged on the first ground connection pads 120 in the peripheral region of the mounting substrate 110 and the first conductive connection member 220 may include a solder ball, for example.

The first molding member 300 on the mounting substrate 110 may cover at least a portion of the first semiconductor chip 200, and may protect the first semiconductor chip 200.

In exemplary embodiments in accordance with principles of inventive concepts, the first molding member 300 may be formed to leave exposed an upper surface of the first semiconductor chip 200. The first molding member 300 may be formed to leave exposed end portions of the first conductive connection members 220. The end portions of the first conductive connection members 220 may protrude from an upper surface of the first molding member 300. Side surfaces of the first semiconductor chip 200 may be covered by the first molding member 300. First molding member 300 may have a thickness below 0.18 mm for example.

In exemplary embodiments in accordance with principles of inventive concepts, the EMI shield member 400 may be arranged over the first molding member 300 to cover the first semiconductor chip 200. The EMI shield member 400 may be supported by the first conductive connection members 220, and may be spaced apart from the first molding member 300 by a predetermined distance. Thus, a space S may be provided between the EMI shield member 400 and the first molding member 300.

The EMI shield member 400 may be adhered to the exposed upper surface of the first semiconductor chip 200 by a thermally conductive adhesive layer 410 and may include a graphite film or a copper film. The EMI shield may have a thickness below 0.1 mm, for example.

The thermally conductive adhesive layer 410 may be adhered to the exposed upper surface of the first semiconductor chip 200. The thermally conductive adhesive layer 410 may have a thermal interface material (TIM) capable of conducting a heat to the EMI shield member 400 and may include an epoxy adhesive.

The first conductive connection members 220 may protrude from the first molding member 300 to contact and support the EMI shield member 400 such that the EMI shield member 400 may be spaced apart from the first molding member 300 by a predetermined distance.

The first ground connection pads 120 may be electrically connected to the outer connection pads 130 on the lower surface 114 of the mounting substrate 110 by inner wirings, respectively. The EMI shield member 400 may be electrically connected to the outer connection members 140 on the outer connection pads 130 by the first conductive connection members 220.

In exemplary embodiments in accordance with principles of inventive concepts, the first molding member 300 may be provided on the mounting substrate 110 to leave exposed the upper surface of the first semiconductor chip 200, and the EMI shield member 400 may be contacted and supported by the first conductive connection members 220 protruding from the first molding member 300 to be spaced apart from the first molding member 300 by a predetermined distance.

In exemplary embodiments in accordance with principles of inventive concepts, the thickness of the semiconductor package 100 may be reduced while, at the same time, EMI shielding and a heat dissipation may be enhanced. Additionally, the EMI shield member 400 may be provided over the first molding member 300 of a thin semiconductor package 100 and be spaced apart from the first molding member 300 in a manner that may prevent the warpage of semiconductor package 100 for example.

Hereinafter, an exemplary embodiment of a method of manufacturing a semiconductor package in accordance with principles of inventive concepts, such as that described in the discussion related to FIG. 1 will be explained.

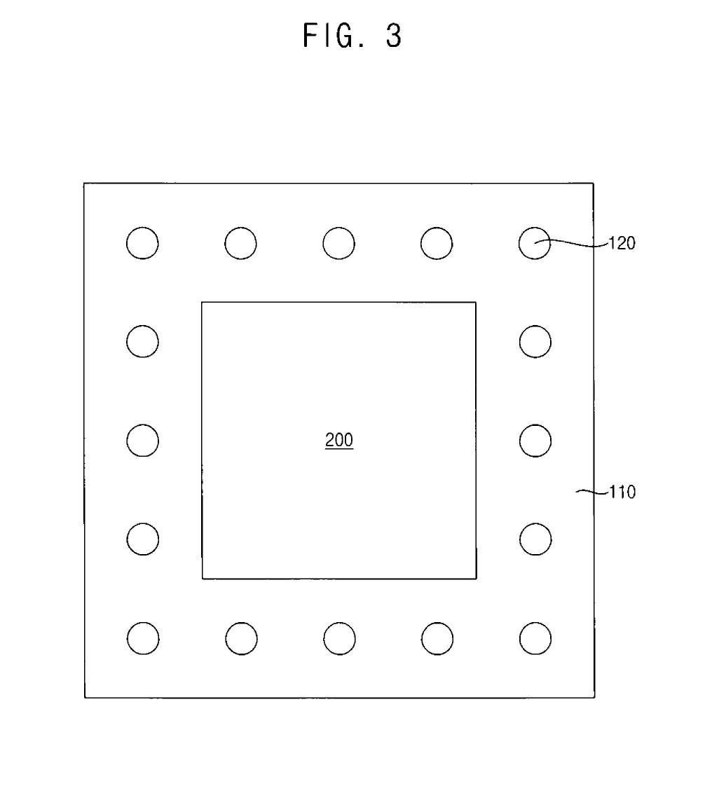

FIGS. 2 and 4 to 6 are cross-sectional views illustrating an exemplary method of manufacturing the semiconductor package. FIG. 3 is a plan view of FIG. 2. The exemplary method may be used to manufacture a semiconductor package such as illustrated in FIG. 1, for example. A mounting substrate 110 having a chip-mounting region and a peripheral region is prepared and a first semiconductor chip 200 may be mounted on the mounting substrate 110. In exemplary embodiments in accordance with principles of inventive concepts, the mounting substrate 110 may be a PCB having an upper surface 112 and a lower surface 114 facing each other. The PCB may be a multi-layered circuit board having various circuits and vias therein.

The mounting substrate 110 may include a chip-mounting region and a peripheral region, for example. The first semiconductor chip 200 may be mounted on the upper surface 112 of the mounting substrate 110 and may be arranged in the chip-mounting region of the mounting substrate 110.

A plurality of first ground connection pads 120 and a plurality of first bonding pads 122 may be formed on the upper surface 112 of the mounting substrate 110, and a plurality of outer connection pads 130 may be formed on the lower surface 114 of the mounting substrate 110.

In exemplary embodiments in accordance with principles of inventive concepts, the plurality of the first ground connection pads 120 may be arranged in the peripheral region, and the plurality of the first bonding pads 122 may be arranged in the chip-mounting region, for example.

The first ground connection pads 120, the first bonding pads 122 and the outer connection pads 130 may be exposed by insulation layer patterns 116 and 118. The insulation layer patterns 116 and 118 may include silicon oxide, silicon nitride, or silicon oxynitride, for example.

The first ground connection pads 120 and the first bonding pads 122 may be electrically connected to the outer connection pads 130 on the lower surface 114 of the mounting substrate 110 by inner wirings thereof.

In exemplary embodiments in accordance with principles of inventive concepts, the first semiconductor chip 200 may be mounted on the mounting substrate 110 by a flip-chip bonding method, for example. The first semiconductor chip 200 may be mounted on the mounting substrate 110 such that an active surface of the first semiconductor chip 200 faces the mounting substrate 110. The first semiconductor chip 200 may be electrically connected to the mounting substrate 110 by bumps 210, which may be solder bumps, for example.

A plurality of the bumps 210 may be arranged on a plurality of the first bonding pads 122, respectively, such that the first semiconductor chip 200 and the mounting substrate 110 may be adhered to each other by the bumps 210. When the first semiconductor chip 200 is adhered to the mounting substrate 110, an adhesive may be underfilled between the first semiconductor chip 200 and the mounting substrate 110. The adhesive may include an epoxy material to reinforce a gap therebetween.

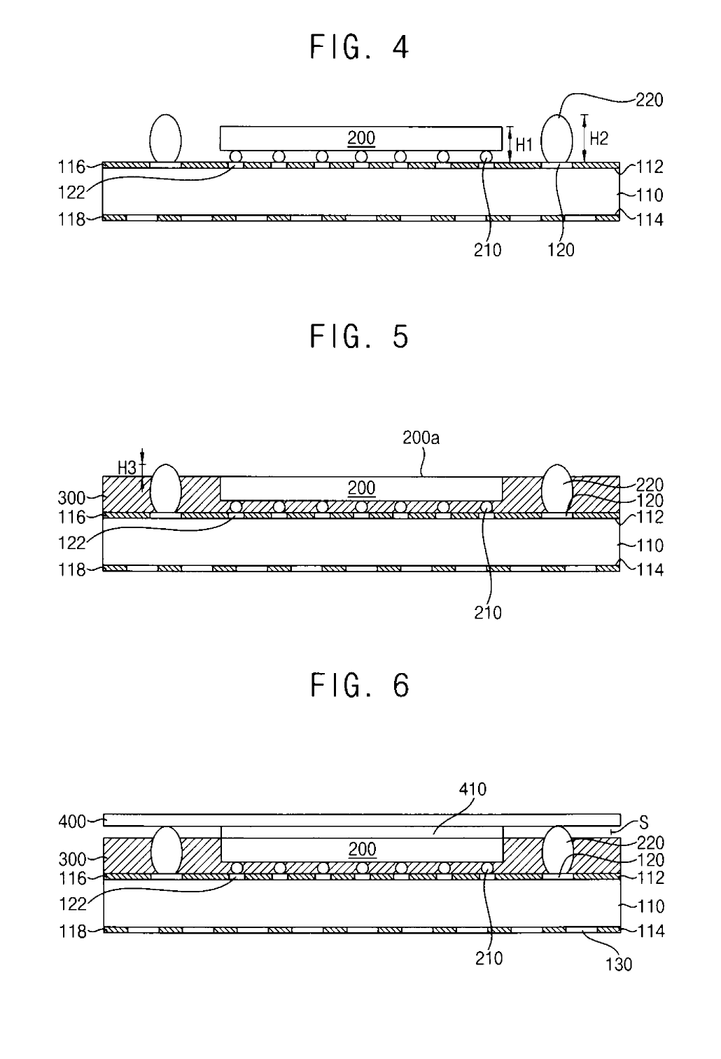

Referring to FIGS. 4 and 5, a first molding member 300 including first conductive connection members 200 formed therein may be formed on the mounting substrate 110.

In an exemplary embodiment in accordance with principles of inventive concepts, the first conductive connection members 220 may be arranged on the first ground connection pads 120 in the peripheral region of the mounting substrate 110, respectively and may include a solder ball, for example.

The first semiconductor chip 200 may have a first height H1 from the mounting substrate 110. The first conductive connection member 220 may have a second height H2, greater than first height H1 from the mounting substrate 110.

First molding member 300 may be formed to cover at least a portion of the first semiconductor chip 200 on the upper surface 112 of the mounting substrate 110. The first molding member 300 may be formed to leave exposed an upper surface 200a of the first semiconductor chip 200. Side surfaces of the first semiconductor chip 200 may be covered by the first molding member 300. First molding member 300 may include epoxy molding compound (EMC), for example.

The first molding member 300 may be formed to leave exposed end portions of the first conductive connection members 220. Accordingly, the end portion of the first conductive connection member 220 may protrude from an upper surface of the first molding member 300 by a third height H3. First molding member 300 may have a thickness below 0.18 mm, for example.

Referring to FIG. 6, an EMI shield member 400 may be formed to cover the first semiconductor chip 200. In exemplary embodiments in accordance with principles of inventive concepts, the EMI shield member 400 may be formed over the first molding member 300 to cover the first semiconductor chip 200. The EMI shield member 400 may be supported by the first conductive connection members 220 to be spaced apart from the first molding member 300 by a predetermined distance. Thus, a space S may be provided between the EMI shield member 400 and the first molding member 300.

The EMI shield member 400 may be adhered to the exposed upper surface of the first semiconductor chip 200 by a thermally conductive adhesive layer 410 and may include a graphite film or a copper film, for example. The EMI shield may have a thickness below 0.1 mm.

The thermally conductive adhesive layer 410 may be adhered to the exposed upper surface of the first semiconductor chip 200 and may have a thermal interface material (TIM) capable of conducting heat to the EMI shield member 400. The TIM may include an epoxy adhesive.

The EMI shield member 400 may be contacted and supported by the first conductive connection members 220 protruding from the first molding member 300 in a manner that leaves it spaced apart from the first molding member 300 by a predetermined distance.

The first ground connection pads 120 may be electrically connected to the outer connection pads 130 on the lower surface 114 of the mounting substrate 110 by inner wirings. Accordingly, the EMI shield member 400 may be electrically connected to outer connection members 140 on the outer connection pads 130 by the first conductive connection members 220.

The outer connection members 140 may be formed on the outer connection pads 130 on the lower surface 114 of the mounting substrate 110 to complete a semiconductor package in accordance with principles of inventive concepts such as semiconductor package 100 illustrated in FIG. 1. Outer connection member 140 may include a solder ball, for example.

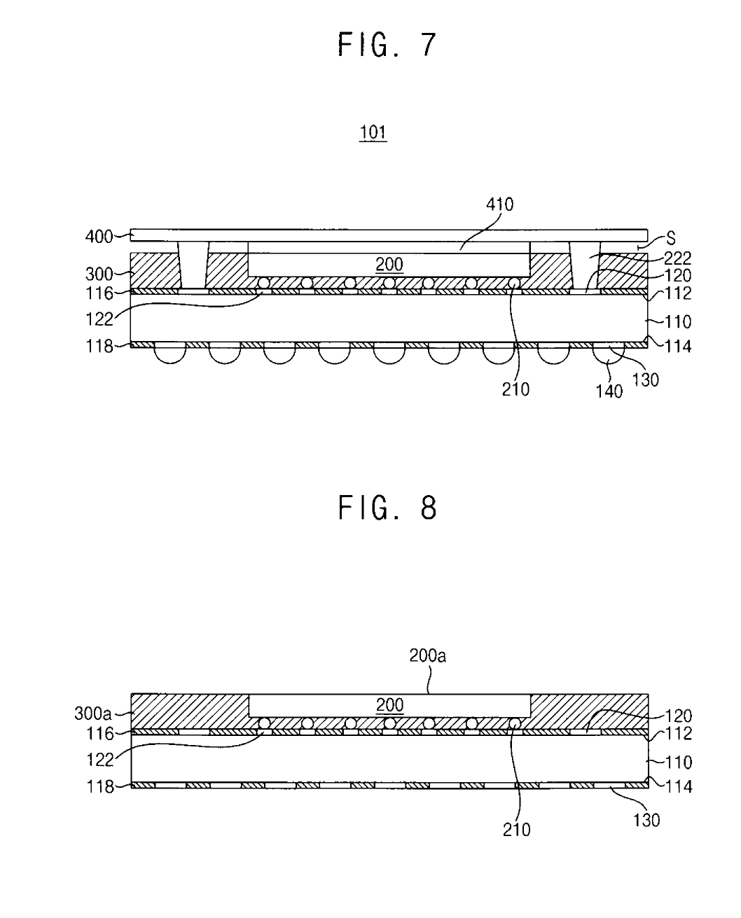

FIG. 7 is a cross-sectional view illustrating an exemplary embodiment of a semiconductor package in accordance with principles of inventive concepts. The semiconductor package may be substantially the same as, or similar to, that of FIG. 1, except for the first conductive connection members. Thus, like reference numerals refer to like elements, and, for brevity and clarity, detailed descriptions of those elements will not be repeated herein.

Referring to FIG. 7, a semiconductor package 101 in accordance with principles of inventive concepts may include a mounting substrate 110, a first semiconductor chip 200 mounted on the mounting substrate 110, a first molding member 300 covering at least a portion of the first semiconductor chip 200, a plurality of first conductive connection members 222 penetrating at least a portion of the first molding member 300 to protrude from the first molding member 300 and provided on a plurality of first ground connection pads 120, and an EMI shield member 400 provided over the first semiconductor chip 200 and supported by the first conductive connection members 222 to be spaced apart from the first molding member 300.

The first ground connection pads 120 for electrical connection with the EMI shield member 400 may be formed on an upper surface 112 of the mounting substrate 110. The first ground connection pads 120 may be arranged in a peripheral region outside a chip-mounting region of the mounting substrate 110, for example.

First bonding pads 122 for electrical connection with the first semiconductor chip 200 may be formed on the upper surface 112 of the mounting substrate 110. The first bonding pads 122 for electrical connection with the first semiconductor chip 200 may be arranged in the chip-mounting region.

The first semiconductor chip 200 may be mounted on the mounting substrate 110 by a flip-chip bonding method, for example. The first semiconductor chip 200 may be electrically connected to the mounting substrate 110 by bumps 210. Although it is not illustrated in the figure, an adhesive may be underfilled between the first semiconductor chip 200 and the mounting substrate 110.

The first molding member 300 may be formed on the upper surface 112 of the mounting substrate 110 to cover at least a portion of the first semiconductor chip 200 and to protect the first semiconductor chip 200. The first molding member 300 may be formed to leave exposed an upper surface of the first semiconductor chip 200.

In this exemplary embodiment, the first molding member 300 may have through-holes that expose the first ground connection pads 120 in the peripheral region of the mounting substrate 110 respectively. The through-holes may be filled with the first conductive connection members 222 respectively. The first conductive connection member 222 may include a conductive material which fills the through-hole. The conductive material may include a solder paste, silver, or epoxy, for example.

The first conductive connection members 222 may fill the through-holes in the first molding member 300 to protrude from the first molding member 300. The EMI shield member 400 may be supported by the first conductive connection members 222 to be spaced apart from the first molding member 300 by a predetermined distance. A space S may be provided between the EMI shield member 400 and the first molding member 300.

The EMI shield member 400 may be adhered to the exposed upper surface of the first semiconductor chip 200 by a thermally conductive adhesive layer 410 and may include a graphite film or a copper film, for example. In exemplary embodiments in accordance with principles of inventive concepts, EMI shield member 400 may have a thickness below 0.1 mm.

The thermally conductive adhesive layer 410 may be adhered to the exposed upper surface of the first semiconductor chip 200 and may have a thermal interface material (TIM) capable of conducting a heat to the EMI shield member 400. The TIM may include an epoxy adhesive, for example.

Thus, a thickness of the semiconductor package 100 may be reduced, while, at the same time, EMI shielding and heat dissipation may be enhanced. Additionally, the EMI shield member 400 may be disposed over the first molding member 300 of a thin semiconductor package 100 and be spaced apart from the first molding member 300 in a manner that may prevent warpage of the semiconductor package 100, for example.

Hereinafter, an exemplary method of manufacturing a semiconductor package in accordance with principles of inventive concepts such as that described in the discussion related to FIG. 7 will be explained.

FIGS. 8 to 11 are cross-sectional views illustrating a method of manufacturing the semiconductor package in accordance with principles of inventive concepts. The method may be used to manufacture a semiconductor package such as that illustrated in FIG. 7, for example. The method may include processes substantially the same as or similar to the processes explained with reference to FIGS. 2 to 6. Thus, like reference numerals refer to like elements, and, for brevity and clarity, detailed descriptions of those elements will not be repeated herein.

Referring to FIG. 8, processes the same as or similar to those that are illustrated with reference to FIGS. 2 to 4 may be performed to mount a first semiconductor chip 200 on a mounting substrate 110.

A plurality of first ground connection pads 120 and a plurality of first bonding pads 122 may be formed on an upper surface 112 of the mounting substrate 110. A plurality of outer connection pads may be formed on a lower surface 114 of the mounting substrate 110. The first ground connection pads 120 may be arranged in a peripheral region of the mounting substrate 110. The first bonding pads 122 may be arranged in a chip-mounting region of the mounting substrate 110.

The first semiconductor chip 200 may be adhered to the chip-mounting region of the mounting substrate 110. The first semiconductor chip 200 may be electrically connected to the mounting substrate 110 by bumps 210. Although it is not illustrated in the figure, when the first semiconductor chip 200 is adhered to the mounting substrate 110, an adhesive may be underfilled between the first semiconductor chip 200 and the mounting substrate 110.

A first preliminary molding member 300a may be formed on the upper surface 112 of the mounting substrate 110 to cover at least a portion of the first semiconductor chip 200. The first preliminary molding member 300a may be formed to leave exposed an upper surface 200a of the first semiconductor chip 200 and may be formed in the peripheral region to cover the first ground connection pads 120.

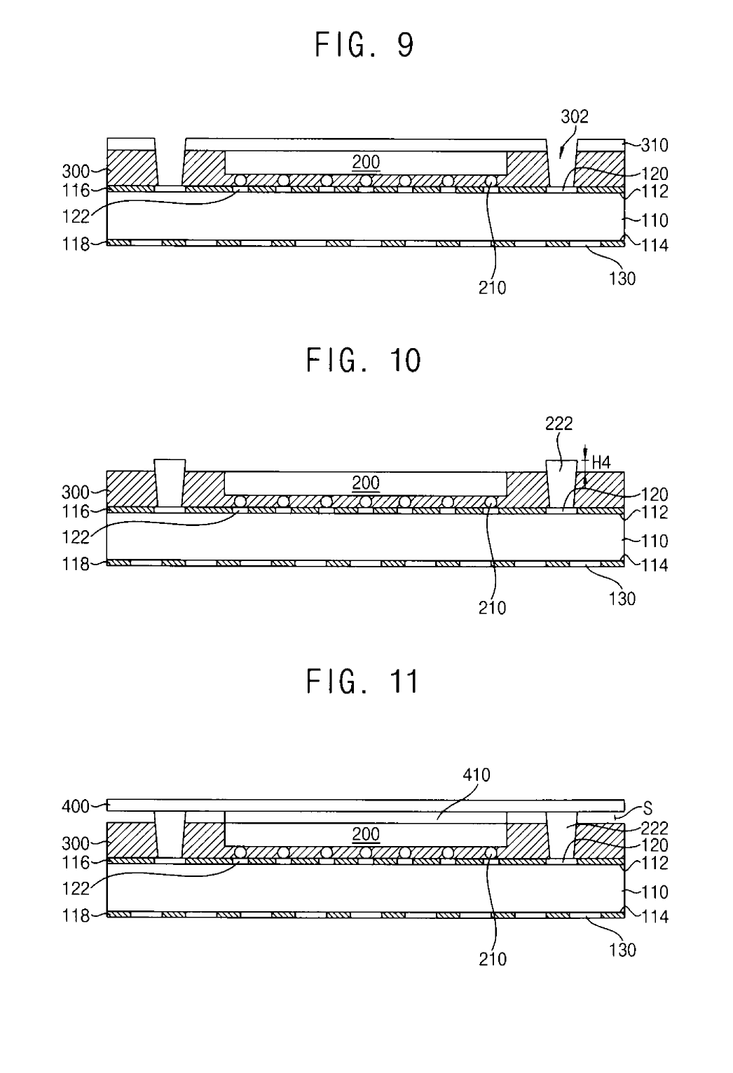

Referring to FIGS. 9 and 10, a first molding member 300 including a plurality of first conductive connection members 222 electrically connected to the first ground connection pads 120 in the peripheral region of the mounting substrate 110, may be formed.

A mask pattern 310 may be formed on the first preliminary molding member 300a, the first preliminary molding member 300a may be partially removed using the mask pattern 310 to form through-holes 302 that expose the first ground connection pads 120 in the peripheral region of the mounting substrate 110 respectively. Through-holes 302 may be formed by a laser drilling process, for example. Accordingly, the first molding member 300 having the through-holes 302 may be formed on the mounting substrate 110.

The through-holes 302 of the first molding member 300 may be filled with a conductive material to form the first conductive connection members 222 contact the first ground connection pads 120, respectively. The conductive material may include a solder paste, silver or epoxy, for example. The first conductive connection member 222 may be formed to protrude from the first molding member 300 by a fourth height H4.

Referring to FIG. 11, an EMI shield member 400 may be formed to cover the first semiconductor chip 200. The EMI shield member 400 may be disposed over the first molding member 300 to cover the first semiconductor chip 200. The EMI shield member 400 may be supported by the first conductive connection members 222 such that the EMI shield member 400 may be spaced apart from the first molding member 300 by a predetermined distance. A space S may be provided between the EMI shield member 400 and the first molding member 300.

The first ground connection pads 120 may be electrically connected to outer connection pads 130 on the lower surface 114 of the mounting substrate 110 by inner wirings, for example. The EMI shield member 400 may be electrically connected to the outer connection pads 130 by the first conductive connection members 222.

Outer connection members such as solder balls (not shown) may be formed on the outer connection pads 130 on the lower surface 114 of the mounting substrate 110, to complete the semiconductor package 101.

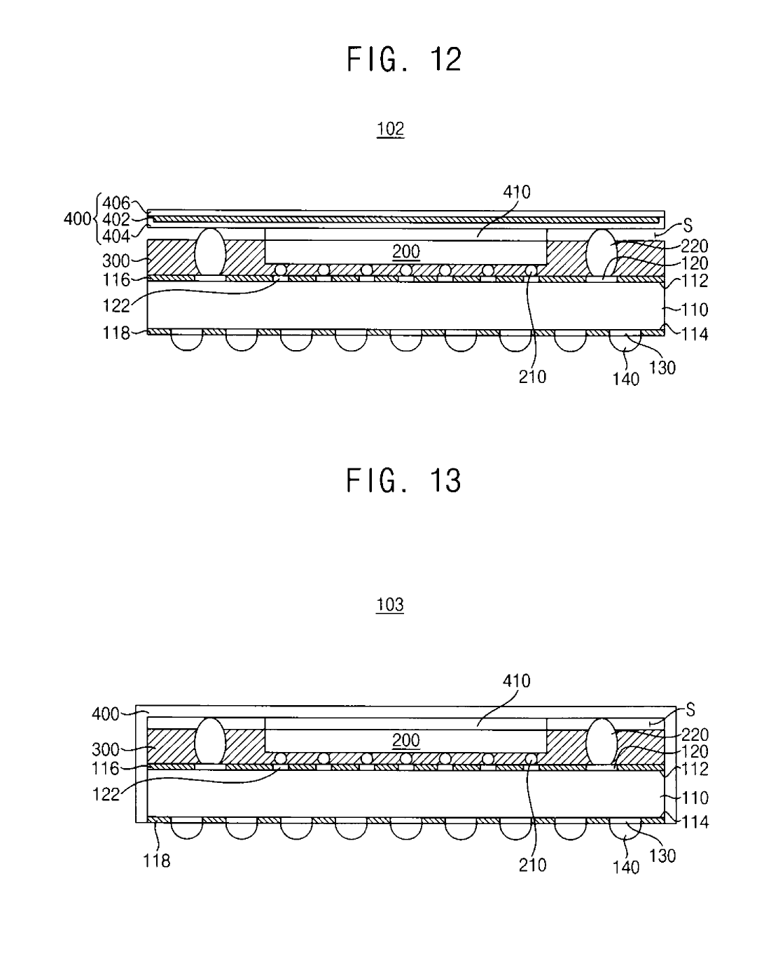

FIG. 12 is a cross-sectional view illustrating an exemplary embodiment of a semiconductor package in accordance with principles of inventive concepts. The semiconductor package may be substantially the same as or similar to that of FIG. 1, except for a connection structure of the EMI shield member. Thus, like reference numerals refer to like elements, and, for brevity and clarity, detailed descriptions of those elements will not be repeated herein.

A semiconductor package 102 in accordance with principles of inventive concepts may include a mounting substrate 110, a first semiconductor chip on the mounting substrate 110, a first molding member 300 covering at least a portion of the first semiconductor chip 200, first conductive connection members 220 protruding from the first molding member 300 through at least a portion thereof in a peripheral region of the mounting substrate 110 and an EMI shield member 400 covering the first semiconductor chip 200 and being spaced apart from the first molding member 300.

In this exemplary embodiment, the EMI shield member 400 may include a graphite layer 402, a support layer 406 supporting the graphite layer 402 and an adhesive layer 404 on the graphite layer 402. The graphite layer 402 may include a graphite tape having high heat conductivity and good EMI shielding performance. The adhesive layer 404 may include a conductive epoxy adhesive and support layer 406 may include polyimide, for example.

The first conductive connection members 220 may protrude from the first molding member 300, with end portions protruding from the first molding member 300 by a predetermined distance, for example.

The graphite layer 402 may be contacted and supported by the first conductive connection members 220 by the conductive adhesive layer 404. The conductive adhesive layer 404 may make contact with the first conductive connection members 220 to electrically connect the graphite layer 402 to the first conductive connection members 220.

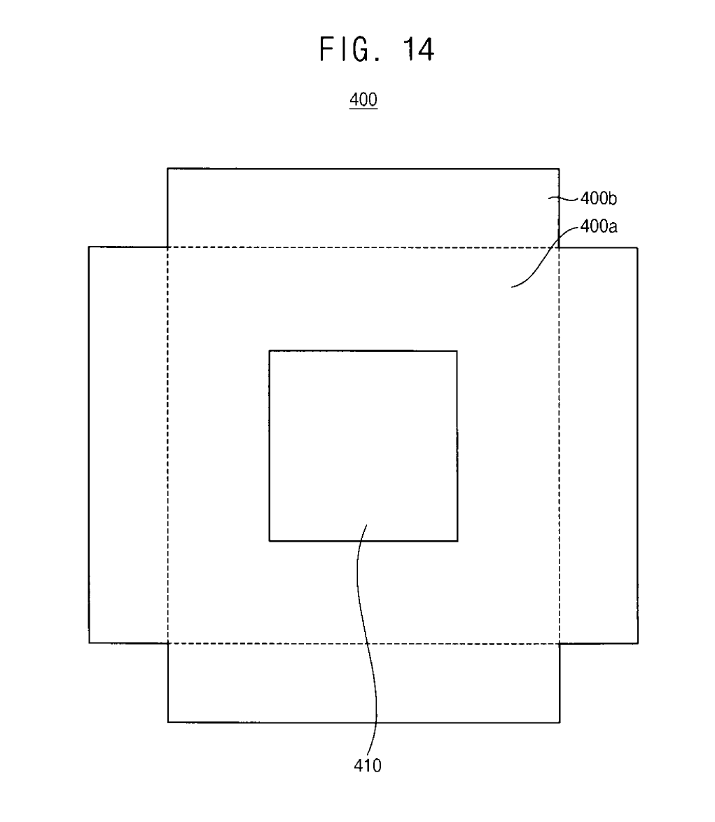

FIG. 13 is a cross-sectional view illustrating an exemplary embodiment of a semiconductor package 103 in accordance with principles of inventive concepts. FIG. 14 is a plan view illustrating an EMI shield member of the semiconductor package 103 in FIG. 13. The semiconductor package 103 may be substantially the same as or similar to that of FIG. 1, except for the EMI shield member. Thus, like reference numerals refer to like elements, and, for clarity and brevity, detailed descriptions of those elements will not be repeated herein.

Referring to FIGS. 13 and 14, a semiconductor package 103 in accordance with principles of inventive concepts may include a mounting substrate 110, a first semiconductor chip on the mounting substrate 110, a first molding member 300 covering at least a portion of the first semiconductor chip 200, first conductive connection members 220 penetrating at least a portion of the first molding member 300 in a peripheral region of the mounting substrate 110 to protrude from the first molding member 300 and an EMI shield member 400 covering the first semiconductor chip 200 and spaced apart from the first molding member 300.

In this exemplary embodiment, the EMI shield member 400 may cover at least an outer side surface of the mounting substrate 110. As illustrated in FIG. 14, the EMI shield member 400 may include a first shielding portion 400a and a second shielding portion 400b.

The first shielding portion 400a may have a shape corresponding to an upper surface 112 of the mounting substrate 110 to cover the upper surface 112 of the mounting substrate 110. The second shielding portion 400b may extend from the first shield member 400a to cover the outer side surface of the mounting substrate 110.

When the first shielding portion 400a is adhered to the first molding member 300 to cover the first semiconductor chip 200, the second shielding portion 400b may be bent and adhered to the outer side surface of the first molding member 300 such that the EMI shield member 400 may be adhered to an outer surface of the mounting substrate 110, for example.

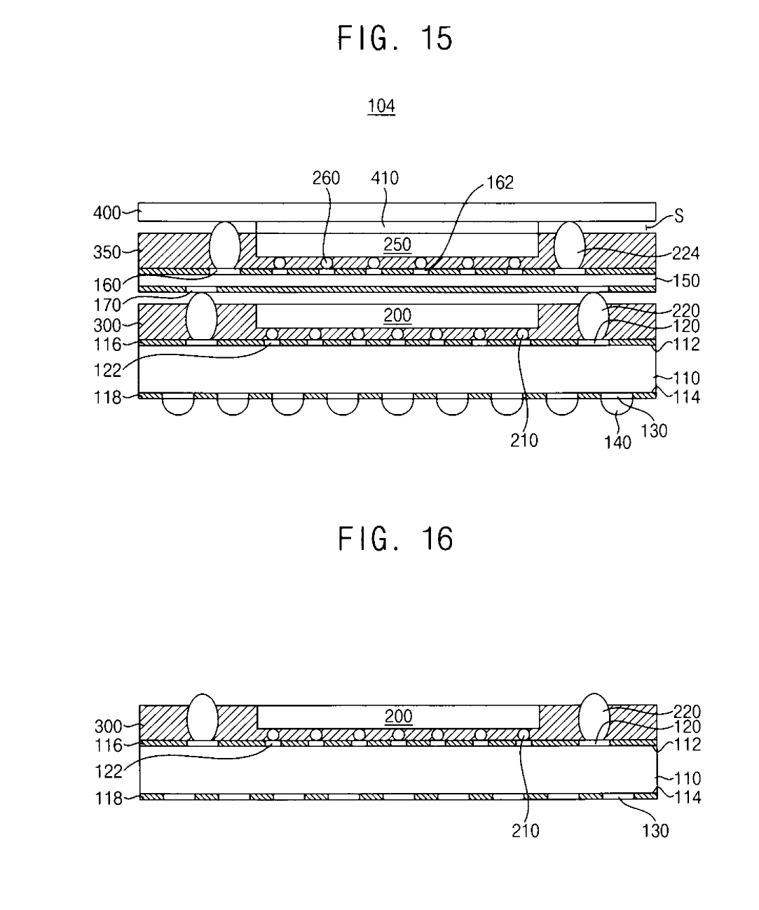

FIG. 15 is a cross-sectional view illustrating an exemplary embodiment of a semiconductor package in accordance with principles of inventive concepts. The semiconductor package 104 may be substantially the same as or similar to that of FIG. 1, except for an additionally stacked semiconductor chip. Thus, like reference numerals refer to like elements, and, for clarity and brevity, detailed descriptions of those elements will not be repeated herein.

Referring to FIG. 15, a semiconductor package 104 may include a first package having a first semiconductor chip 200 and a second package having a second semiconductor chip 250 over the first package.

The first package may include a mounting substrate 110, a first semiconductor chip 200 mounted on the mounting substrate 110, a first molding member 300 covering at least a portion of the first semiconductor chip 200 and first conductive connection members 220 penetrating through at least a portion of the first molding member 300 around the first semiconductor chip 200.

The second package may include a redistribution wiring substrate 150 on the first molding member 300, the second semiconductor chip 250 mounted on a chip-mounting region of the redistribution wiring substrate 150, a second molding member 350 covering at least a portion of the second semiconductor chip 250, second conductive connection members 224 penetrating at least a portion of the second molding member 350 to protrude from the second molding member 350 and an EMI shield member 400 covering the first and second semiconductor chips 200 and 250 and spaced apart from the second molding member 350.

In this exemplary embodiment, the redistribution wiring substrate 150 may have an upper surface and a lower surface facing each other. The redistribution wiring substrate 150 may be a multi-layered circuit board having various circuits and vias therein, for example.

The second semiconductor chip 250 may be mounted on the chip-mounting region of the redistribution wiring substrate 150. At least one second semiconductor chip 250 may be mounted on the redistribution wiring substrate 150, however, the number of the stacked second semiconductor chips 250 is not limited thereto.

Second ground connection pads 160 for electrical connection with the EMI shield member 400 may be formed on the upper surface of the redistribution wiring substrate 150. The second ground connection pads 160 may be arranged in a peripheral region outside the chip-mounting region of the redistribution wiring substrate 150, for example.

Second bonding pads 162 for electrical connection with the second semiconductor chip 250 may be formed on the upper surface of the redistribution wiring substrate 150. The second bonding pads 162 may be arranged in the chip-mounting region.

Redistribution wiring connection pads 170 for electrical connection with the first conductive connection members 220 may be formed on the lower surface of the redistribution wiring substrate 150.

A plurality of the second bonding pads 162 and a plurality of the second ground connection pads 160 may be exposed by insulation layer patterns on the redistribution wiring substrate 150. The insulation layer pattern may include silicon oxide, silicon nitride, or silicon oxynitride, for example.

The second bonding pads 162 and the second ground connection pads 160 may be electrically connected to the redistribution wiring connection pads 170 by inner wirings of the redistribution wiring substrate 150, for example.

The second semiconductor chip 250 may be mounted on the redistribution wiring substrate 150 such that an active surface of the second semiconductor chip 250 faces the redistribution wiring substrate 150. Second semiconductor chip 250 may be electrically connected to the redistribution wiring substrate 150 by bumps 260, for example.

The first conductive connection members 220 may be arranged on first ground connection pads 120 in the peripheral region of the mounting substrate 110 and may be solder balls, for example.

The first conductive connection members 220 may protrude from the first molding member 300, with end portions protruding by a predetermined distance, for example.

The redistribution wiring substrate 150 having the second semiconductor chip 250 thereon may be stacked on the first molding member 300 by the first conductive connection members 220. The end protruding portions of the first conductive connection members 220 may be electrically connected to the redistribution wiring connection pads 170 on the lower surface of the redistribution wiring substrate 150, respectively. Although it is not illustrated in the figures, the redistribution wiring substrate 150 may be adhered to upper surfaces of the first molding member 300 and/or the first semiconductor chip by an adhesive layer.

Redistribution wiring substrate 150 may be electrically connected to the first conductive connection members 220.

The second conductive connection members 224 may be arranged on the second ground connection pads 160 in the peripheral region of the redistribution wiring substrate 150, respectively and may include a solder ball, for example.

The second molding member 350 may be formed on the upper surface of the redistribution wiring substrate 150 to cover at least a portion of the second semiconductor chip 250 and to protect the second semiconductor chip 250.

The second molding member 350 may be formed to leave exposed an upper surface of the second semiconductor chip 250. The second molding member 350 may be formed to leave exposed end portions of the second conductive connection members 224. The end portions of the second conductive connection members 224 may protrude from the second molding member 350. Side surfaces of the second semiconductor chip 250 may be covered by the second molding member 350.

The EMI shield member 400 may be disposed over the second molding member 350 to cover the first and the second semiconductor chips 200 and 250. The EMI shield member 400 may be supported by the second conductive connection members 224 to be spaced apart by the second molding member 350 by a predetermined distance. A space S may be provided between the EMI shield member 400 and the second molding member 350.

The EMI shield member 400 may be electrically connected to outer connection members 140 on outer connection pads 130 of the mounting substrate 110 by the first and the second conductive connection members 220 and 224, respectively.

In this exemplary embodiment, the semiconductor package 104 may be a system in package (SIP). The first semiconductor chip 200 may be a logic chip including a logic circuit. The second semiconductor chip 250 may be a memory chip including a memory circuit. The memory circuit may include a memory cell region for storing data and/or a memory logic region for operating the memory chip, for example.

The first semiconductor chip 200 may include a circuit portion having functional circuits that may include a transistor or a passive device such as resistor, or capacitor, for example. The functional circuits may include a memory control circuit, an external input/output circuit, a micro input/output circuit and/or an additional functional circuit, for example. The memory control circuit may provide a data signal and/or a memory control signal for operating the second semiconductor chip 250. The memory control signal may include address signal, command signal, or clock signal, for example.

In this exemplary embodiment, data signal connection pads and control signal connection pads may be formed on the upper surface of the mounting substrate 110. The data signal connection pads and the control signal connection pads may be arranged on the peripheral region together with the first ground connection pads 120.

Additionally, conductive connection members may be arranged on the data signal connection pads and the control signal connection pads. The conductive connection members may be solder balls like the first conductive connection members 220, for example.

The conductive connection members on the data signal connection pads and the control signal connection pads may protrude from the first molding member 300 and protruding end portions of the first conductive connection members 220 may be electrically connected to the redistribution wiring connection pads 170 on the lower surface of the redistribution wiring substrate 150, respectively.

Thus, the conductive connection members on the data signal connection pads and the control signal connection pads may be used as an electrical path for transmitting a signal or power required to operate the second semiconductor chip 250. The signal may include a data signal and a control signal. The power may include a power voltage (VDD) and a ground voltage (VSS), for example.

In this exemplary embodiment, the data signal and/or the control signal may be transmitted from the memory control circuit of the first semiconductor chip 200 to the second semiconductor chip 250. The power voltage (VDD) and/or the ground voltage (VSS) may be supplied to the second semiconductor chip 250 through the mounting substrate 110.

Hereinafter, an exemplary method of manufacturing a semiconductor package such as the semiconductor package described in the discussion related to FIG. 15 will be described.

FIGS. 16 to 18 are cross-sectional views illustrating a method of manufacturing a semiconductor package in accordance with principles of inventive concepts. The method may be used to manufacture the semiconductor package illustrated in FIG. 15, however, it is not limited thereto. The method may be substantially the same as or similar to the processes explained with reference to FIGS. 2 to 6. Thus, like reference numerals refer to like elements, and, for brevity and clarity, detailed descriptions of those elements will not be repeated herein.

Referring to FIG. 16, processes the same as or similar to the processes explained with reference to FIG. 2, FIG. 4 and FIG. 5 may be performed such that a first semiconductor chip 200 may be mounted on a mounting substrate 110 and a first molding member 300 may be formed to cover at least a portion of the first semiconductor chip 200, for example.

A plurality of first ground connection pads 120 and a plurality of first bonding pads 122 may be formed on an upper surface 112 of the mounting substrate 110. A plurality of outer connection pads 130 may be formed on a lower surface of the mounting substrate 110. The first ground connection pads 120 may be arranged in a peripheral region of the mounting substrate 110 and the first bonding pads 122 may be arranged in a chip-mounting region of the mounting substrate 110.

Data signal connection pads and control signal connection pads may be formed on the upper surface 112 of the mounting substrate 110. The data signal connection pads and control signal connection pads may be arranged in the peripheral region of the mounting substrate 110 together with the first ground connection pads 120, for example.

A first semiconductor chip 200 may be mounted on the chip-mounting region of the mounting substrate 110. The first semiconductor chip 200 may be electrically connected to the mounting substrate 110 by bumps 210. Although it is not illustrated, when the first semiconductor chip 200 is adhered to the mounting substrate 110, an adhesive may be underfilled between the first semiconductor chip 200 and the mounting substrate 110.

First conductive connection members 220 may be arranged on the first ground connection pads 120 in the peripheral region, respectively and may be solder balls, for example. The first conductive connection members 220 may protrude from the first molding member 300, with end portions of the first conductive connection members 220 protruding from the first molding member 300 by a predetermined distance.

Conductive connection members may be arranged on the data signal connection pads and the control signal connection pads and may be solder balls as the first conductive connection members 220. The conductive connection members on the data signal connection pads and the control signal connection pads may protrude from the first molding member 300.

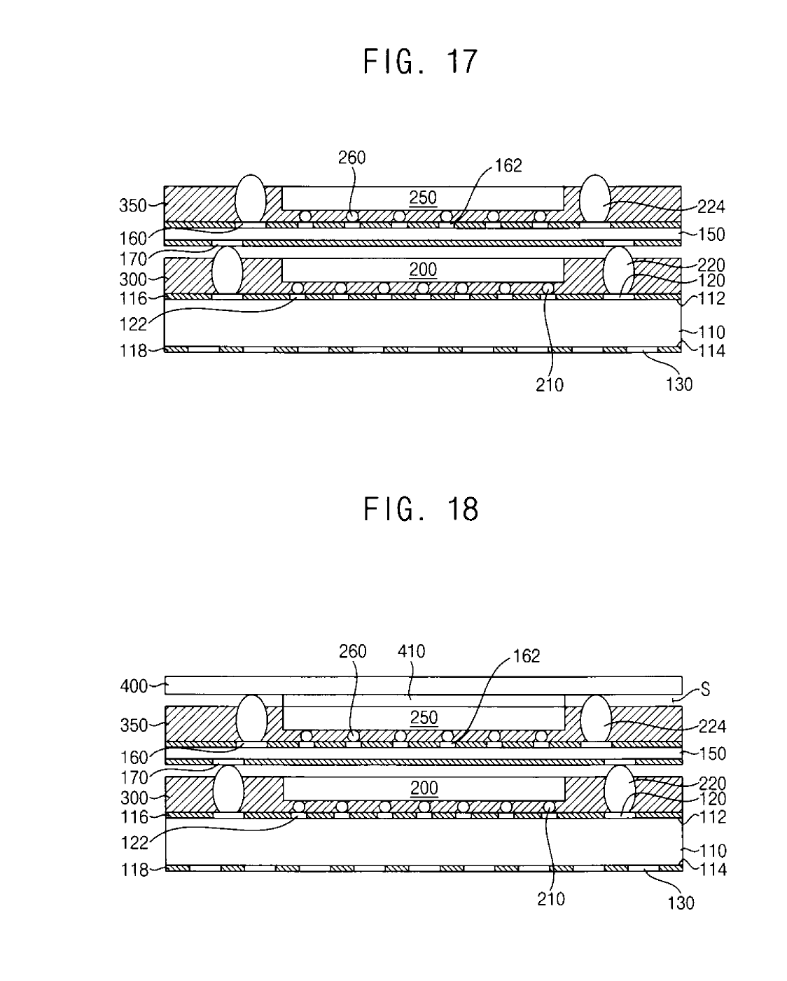

Referring to FIG. 17, a redistribution wiring substrate 150 may be stacked over the first molding member 300 to be electrically connected to the first conductive connection members 220.

Second ground connection pads 160 may be arranged on an upper surface of the redistribution wiring substrate 150 in a peripheral region thereof. Second bonding pads 162 may be arranged on the upper surface of the redistribution wiring substrate 150 in a chip-mounting region thereof. Redistribution wiring connection pads 170 may be formed on a lower surface of the redistribution wiring substrate 150 to be electrically connected to the first conductive connection members 220.

A second semiconductor chip 250 may be mounted on the redistribution wiring substrate 150 such that active surface thereof faces the redistribution wiring substrate 150. The second semiconductor chip 250 may be electrically connected to the redistribution wiring substrate 150 by bumps 260.

Second conductive connection members 224 may be arranged on the second ground connection pads 160 in the peripheral region of the redistribution wiring substrate 150 and may be solder balls, for example.

A second molding member 350 may be formed on the redistribution wiring substrate 150 to cover at least a portion of the second semiconductor chip 250. The second molding member 350 may be formed to leave exposed end portions of the second conductive connection members 224. The second conductive connection members may be exposed by the second molding member 350.

As it is illustrated in FIG. 17, the redistribution wiring substrate 150 having the second semiconductor chip 250 mounted thereon may be stacked over the first molding member 300 by the first conductive connection members 220. The protruding end portions of the first conductive connection members 220 may be electrically connected to the redistribution wiring connection pads 170 on the lower surface of the redistribution wiring substrate 150. Although it is not illustrated in figure, the redistribution wiring substrate may be adhered to upper surfaces of the first molding member 300 and/or the first semiconductor chip 200.

The end portions of the first conductive connection members 220 protruding from the first molding member 300 may be electrically connected to the redistribution wiring connection pads 170 on the lower surface of the redistribution wiring substrate 150.

Additionally, the conductive connection members on the data signal connection pads and the control signal connection pads may be electrically connected to the redistribution wiring connection pads on the lower surface of the redistribution wiring substrate 150.

Referring to FIG. 18, an EMI shield member 400 may be formed to cover the first and the second semiconductor chips 200 and 250. The EMI shield member 400 may be arranged over the second molding member 350 to cover the second semiconductor chip 250. The EMI shield member 400 may be supported by the second conductive connection members 224 to be spaced apart from the second molding member 350 by a predetermined distance. A space S may be formed between the EMI shield member 400 and the second molding member 350.

Outer connection members (not shown) may be formed on the outer connection pads 130 on the lower surface 114 of the mounting substrate 110 to complete the semiconductor package 104.

The EMI shield member 400 may be electrically connected to the outer connection members (not shown) on the outer connection pads 130 by the first and the second conductive connection members 220 and 224, for example.

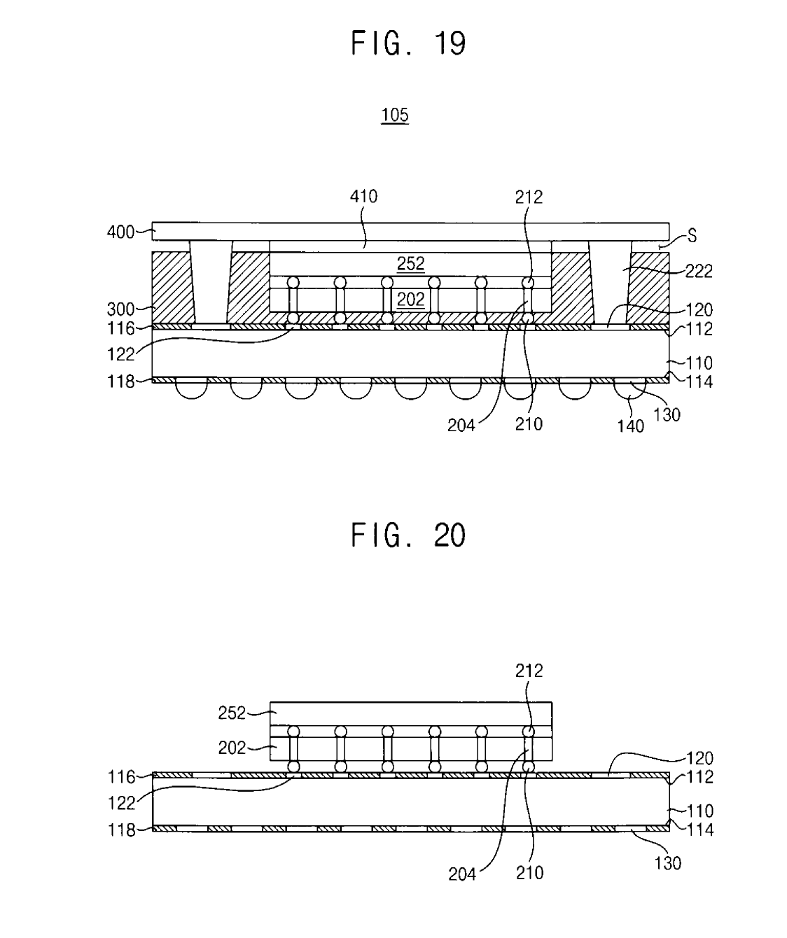

FIG. 19 is a cross-sectional view illustrating an exemplary embodiment of a semiconductor package in accordance with principles of inventive concepts. The semiconductor package may be substantially the same as or similar to that of FIG. 7, except for a structure of the stacked semiconductor chip. Thus, like reference numerals refer to like elements, and, for brevity and clarity, detailed descriptions of those elements will not be repeated herein.

Referring to FIG. 19, a semiconductor package 105 in accordance with principles of inventive concepts may include a mounting substrate 110, a first semiconductor chip 202 mounted on the mounting substrate 110, a third semiconductor chip 252 stacked on the first semiconductor chip 202, a first molding member 300 covering at least portions of the first and the third semiconductor chips 202 and 252, a plurality of first conductive connection members 222 on a plurality of first ground connection pads 120 in a peripheral region of the mounting substrate 110 and penetrating at least a portion of the first molding member 300 to protrude from the first molding member 300 and an EMI shield member 400 covering the first and the third semiconductor chips 202 and 252 and being spaced apart from the first molding member 300.

The third semiconductor chip 252 may be stacked on the first semiconductor chip 202 and may be electrically connected to the first semiconductor chip 202 by a plurality of bumps 212.

The first semiconductor chip 202 may include plugs 204 penetrating therethrough. A through-electrode referred to as through silicon via (TSV) may be used as the plugs 204.

The bumps 212 may be arranged on end portions of the through electrodes of the first semiconductor chip 202 to electrically connect the first semiconductor chip 202 and the third semiconductor chip 252. Thus, the third semiconductor chip 202 may be electrically connected to the first semiconductor chip 202 by a plurality of the through electrodes penetrating through the first semiconductor chip 202.

The first molding member 300 may be formed on an upper surface of the mounting substrate 110 to cover portions of the first and the third semiconductor chips 202 and 252. The first molding member 300 may be formed to leave exposed an upper surface of the second semiconductor chip 252.

The first molding member 300 may have through-holes that expose the first ground connection pads 120 in a peripheral region of the mounting substrate 110. The through-holes may be filled with the first conductive connection members 222. The first conductive connection members 222 may include a conductive material such as, for example, a conductive paste.

The first conductive connection members 222 may fill the through-holes to protrude from the first molding member 300. The EMI shield member 400 may be electrically connected to the first conductive connection members 222 protruding from the first molding member 300. Additionally, the EMI shield member 400 may be supported by the first protruding conductive connection members 222 and may be spaced apart from the first molding member 300.

Hereinafter, an exemplary method of manufacturing a semiconductor package such as that described in the discussion related to FIG. 19 will be described.

FIGS. 20 to 22 are cross-sectional views illustrating the method of manufacturing the semiconductor package in accordance with principles of inventive concepts. The method may be used to manufacture the semiconductor package illustrated in FIG. 20, however, it is not limited thereto. The exemplary method may be substantially the same as or similar to those of FIGS. 8 to 11. Thus, like reference numerals refer to like elements, and, for clarity and brevity, detailed descriptions of those elements will not be repeated herein.

Referring to FIG. 20, a first and a third semiconductor chips 202 and 252 may be stacked on a mounting substrate 110.

The third semiconductor chip 252 may be stacked on the first semiconductor chip 202 by a plurality of bumps 212. The first semiconductor chip 202 may include plugs 204 penetrating through the first semiconductor chip 202. A through-electrode referred to herein as through silicon via (TSV) may be used as the plugs 204.

The bumps 212 may be arranged on end portions of the through electrodes of the first semiconductor chip 202. The third semiconductor chip 252 may be stacked on the first semiconductor chip 202 by a reflow process. The third semiconductor chip 252 may be electrically connected to the first semiconductor chip 202 by a plurality of the through electrodes penetrating through the first semiconductor chip 202.

The first and the third semiconductor chips 202 and 252 may be mounted on the mounting substrate 110. The first semiconductor chip 202 may be electrically connected to the mounting substrate 110 by bumps 210.

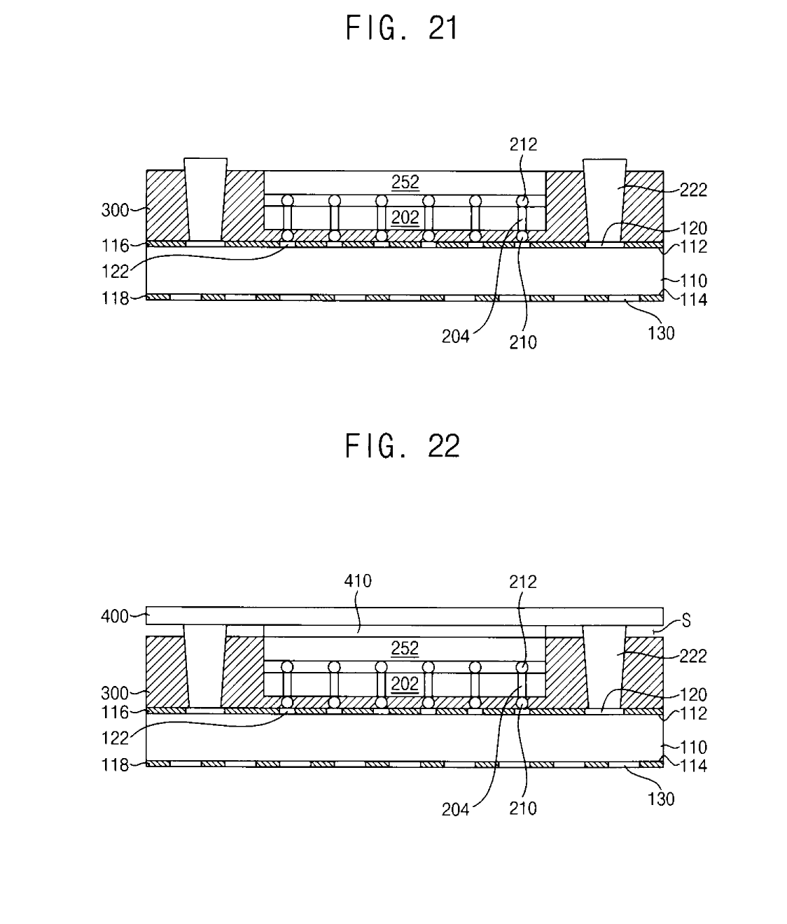

Referring to FIG. 21, a first molding member 300 having first conductive connection members 222 for electrical connection with first ground connection pads 120 may be formed on an upper surface 112 of the mounting substrate 110.

A first preliminary molding member may be formed on the upper surface 112 of the mounting substrate 110 to cover at least portions of the first and the third semiconductor chips 202 and 252. The first preliminary molding member may be formed to leave exposed an upper surface of the third semiconductor chip 252. The first preliminary molding member may cover side surfaces of the first and the third semiconductor chips 202 and 252. The first preliminary molding member may be formed in the peripheral region of the mounting substrate 110 to cover the first ground connection pads 120.

The first preliminary molding member may be partially removed to form through-holes that expose the first ground connection pads 120 in the peripheral region respectively. For example, the through-holes may be formed by a laser drilling process. The first molding member 300 having the through-holes therein may be formed on the mounting substrate 110.

The through-holes of the first molding member 300 may be filled with a conductive material to form the first conductive connection members 222 that contact the first ground connection pads 120 respectively, for example. The conductive material may include a conductive paste. The first conductive connection members 222 may be formed to protrude from the first molding member 300.

Referring to FIG. 22, an EMI shield member 400 may be formed to cover the first and the third semiconductor chips 202 and 252.

The EMI shield member 400 may be arranged over the first molding member 300. The EMI shield member 400 may be supported by the first conductive connection members 222 and may be spaced apart from the first molding member 300. A space S may be provided between the EMI shield member 400 and the first molding member 300.

The first ground connection pads 120 may be electrically connected to outer connection pads 130 on a lower surface of the mounting substrate 110 by inner wirings thereof. The EMI shield member 400 may be electrically connected to the outer connection pads 130 by the first conductive connection members 222.

Outer connection members (not shown), e.g., solder balls may be formed on the outer connection pads 130 on the lower surface 114 of the mounting substrate 110 to complete the semiconductor package 105.

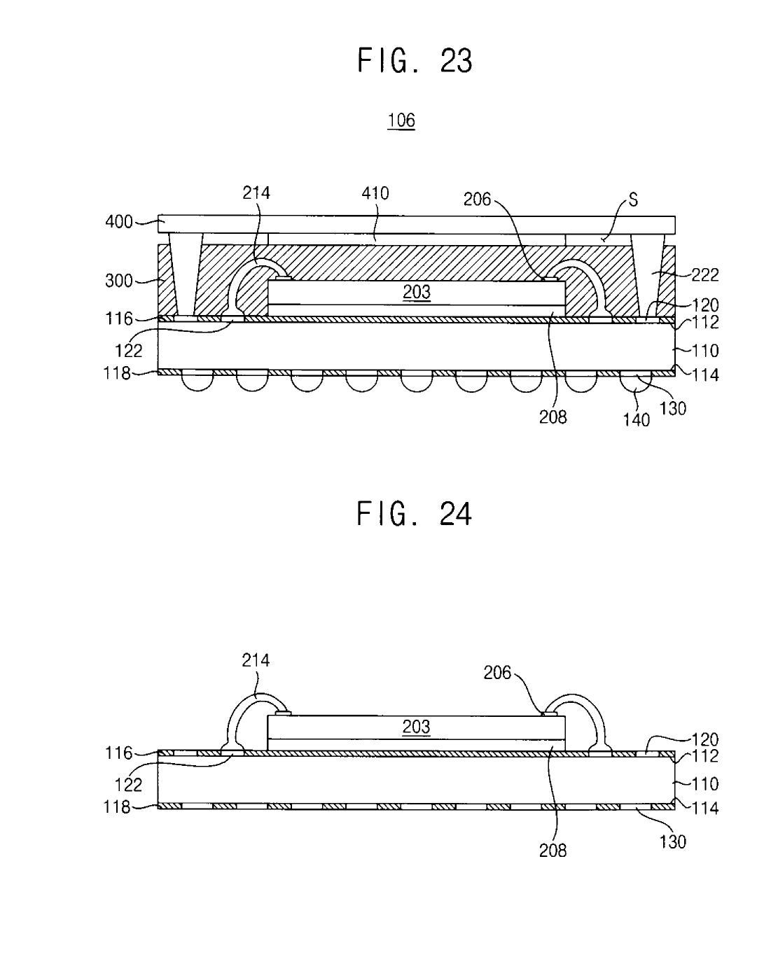

FIG. 23 is a cross-sectional view illustrating an exemplary embodiment of a semiconductor package in accordance with principles of inventive concepts. The semiconductor package may be substantially the same as or similar to that of FIG. 7, except for a connection structure of the mounting substrate and the semiconductor chip. Thus, like reference numerals refer to like elements, and, for brevity and clarity detailed descriptions of those elements will not be repeated herein.

Referring to FIG. 23, a semiconductor package 106 in accordance with principles of inventive concepts may include a mounting substrate 110, a first semiconductor chip 203 mounted on the mounting substrate 110, a first molding member 300 covering at least a portion of the first semiconductor chip 203, a plurality of first conductive connection members 222 on a plurality of first ground connection pads 120 in a peripheral region of the mounting substrate 110 and penetrating at least a portion of the first molding member 300 to protrude from the first semiconductor chip 203 and an EMI shield member 400 for electrical connection with the first conductive connection members 222 covering the first semiconductor chip 203 and being spaced apart from the first molding member 300.

The first semiconductor chip 203 may be adhered to the mounting substrate 110 by an adhesive layer 208. Chip pads 206 may be formed on an upper surface of the first semiconductor chip 203. Bonding wires 214 may be drawn from first bonding pads 122 to be connected to the chip pads 206 of the first semiconductor chip 203, respectively.

The first molding member 300 may be formed on an upper surface 112 of the mounting substrate 110 to cover the first semiconductor chip 203. The first molding member 300 may have through-holes that expose the first ground connection pads 120 in the peripheral region respectively. The through-holes may be filled with the first conductive connection members 222. The first conductive connection members 222 may include a conductive material, e.g., a conductive paste, which fills the through-holes.

The first conductive connection members 222 may fill the through-holes to protrude from the first molding member 300. The EMI shield member 400 may be formed on the first molding member 300 and may be electrically connected to the first conductive connection members 222 protruding from the first molding member 300.

Hereinafter, an exemplary method of manufacturing a semiconductor package such as that described in the discussion related to FIG. 23 will be described.

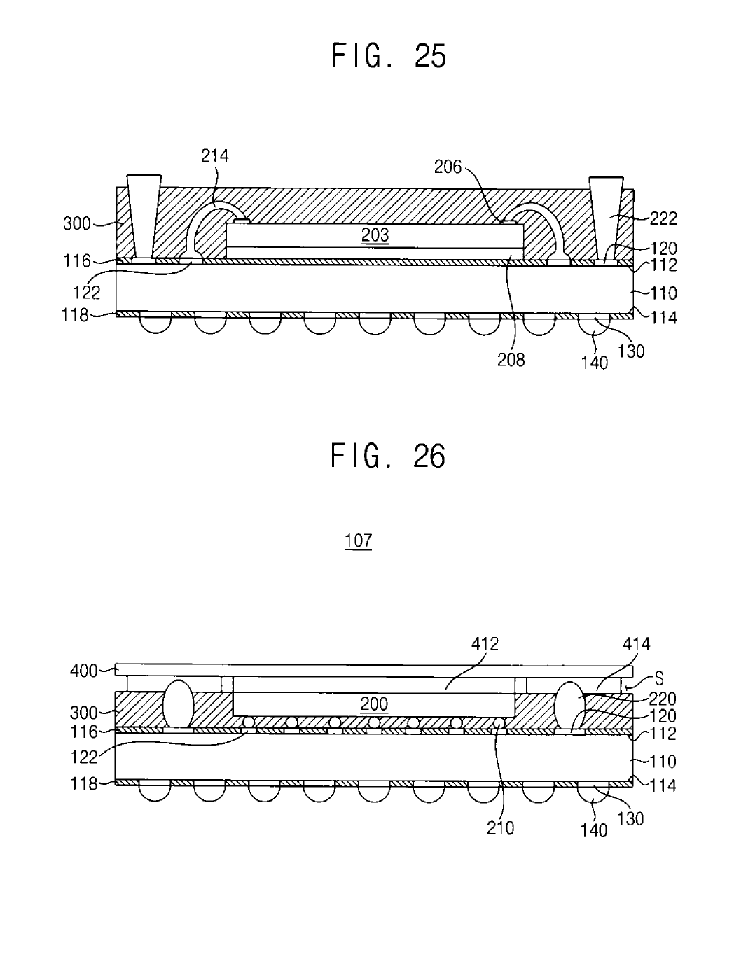

FIGS. 24 to 25 are cross-sectional views illustrating the method of manufacturing the semiconductor package in accordance with principles of inventive concepts. The method may be used to manufacture a semiconductor package such as that illustrated in FIG. 23, however, it is not limited thereto. The method may be substantially the same as or similar to the processes that explained with reference to FIGS. 8 to 11. Thus, like reference numerals refer to like elements, and, for brevity and clarity, detailed descriptions of those elements will not be repeated herein.

Referring to FIG. 24, a first semiconductor chip 230 may be stacked on a mounting substrate 110 and may be adhered to the mounting substrate 110 using an adhesive layer 208 thereon. The mounting substrate 110 and the first semiconductor chip 203 may be electrically connected to each other by a plurality of bonding wires 214. The bonding wires 214 may be drawn to first bonding pads 122 of the mounting substrate 110 to be connected to chip pads 206 of the first semiconductor chip 203. The first semiconductor chip 203 may be electrically connected to the mounting substrate 110 by the bonding wires 214.

Referring to FIG. 25, a first molding member 300 having first conductive connection members 222 for electrical connection with first ground connection pads 120 may be formed on the mounting substrate 110.

A first preliminary molding member may be formed to cover the first semiconductor chip 203 on an upper surface 112 of the mounting substrate 110. The first preliminary molding member may be partially removed to form through-holes exposing the first ground connection pads 120 in the peripheral region of the mounting substrate 110. Through-holes may be formed by a laser drilling process, for example. The first molding member 300 having the through-holes may be formed on the mounting substrate 110.

The through-holes of the first molding member 300 may be filled with a conductive material to form the first conductive connection members 222 that contact the first ground connection pads 120 respectively. The conductive material may include a conductive paste. The first conductive connection members 222 may be formed to be exposed from the first molding member 300.

Referring again to FIG. 23, an EMI shield member 400 may be formed to cover the first semiconductor chip 203 to be electrically connected to the first conductive connection members 222. Outer connection members 140 may be formed on outer connection pads 130 on a lower surface 114 of the mounting substrate 110 to complete the semiconductor package 106.

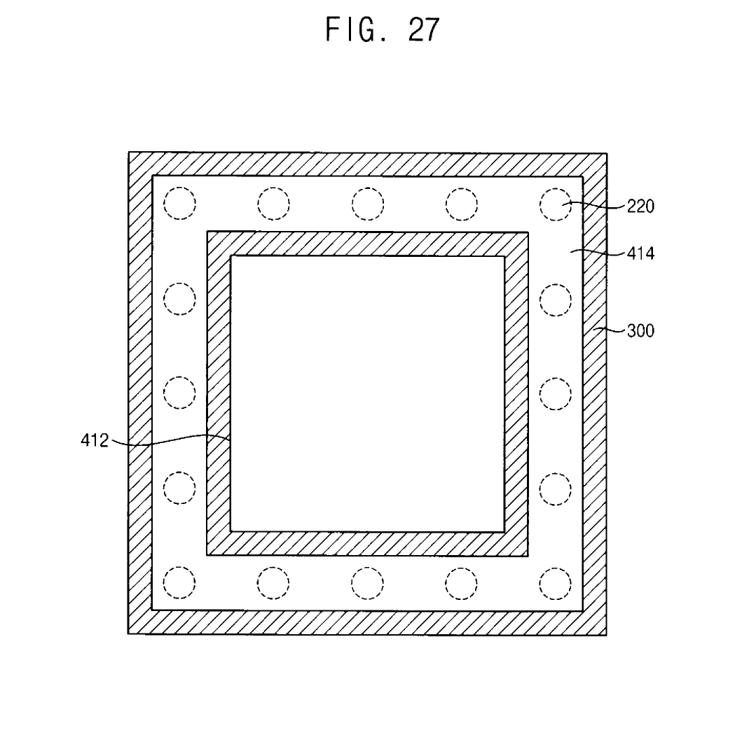

FIG. 26 is a cross-sectional view illustrating an exemplary embodiment of a semiconductor package in accordance with principles of inventive concepts. FIG. 27 is a plan view illustrating an adhesive layer interposed between a molding member and an EMI shielding member of FIG. 26. The semiconductor package may be substantially the same as or similar to that of FIG. 1, except for the addition of a conductive adhesive layer. Thus, like reference numerals refer to like elements, and, for brevity and clarity, detailed descriptions of those elements will not be repeated herein.

Referring to FIG. 26, a semiconductor package 107 in accordance with principles of inventive concepts may include a mounting substrate 100, a first semiconductor chip 200 mounted thereon, a first molding member 300 covering at least a portion of the first semiconductor chip 200, a plurality of first conductive connection members 220 penetrating through at least a portion of the first molding member 300 and an EMI shield member 400 covering the first semiconductor chip 200.

The first molding member 300 may be formed to leave exposed an upper surface of the first semiconductor chip 200. The first molding member 300 may be formed to leave exposed end portions of the first conductive connection members 220. For example, the first conductive connection members 220 may be solder balls. The end portions of the first conductive connection members 220 may protrude from an upper surface of the first molding member 300.

The EMI shield member 400 may be adhered to the exposed upper surface of the first semiconductor chip 200 by a first adhesive layer 412, for example. A second adhesive layer 414 may be arranged in a space S provided between the EMI shield member 400 and the first molding member 300. The second adhesive layer 414 may cover the protruding first conductive connection members 220.

The first adhesive layer 412 may include a nonconductive TIM and the second adhesive layer 414 may include a conductive TIM. The EMI shield member 400 may be electrically connected to the first conductive connection members 220 by the second conductive adhesive layer 414, for example.

As illustrated in FIG. 27, the second adhesive layer 414 may have a linear pattern of a closed loop extending along the first conductive connection members 220. For example, the second adhesive layer 414 may be coated to cover the first protruding conductive connection members 220.

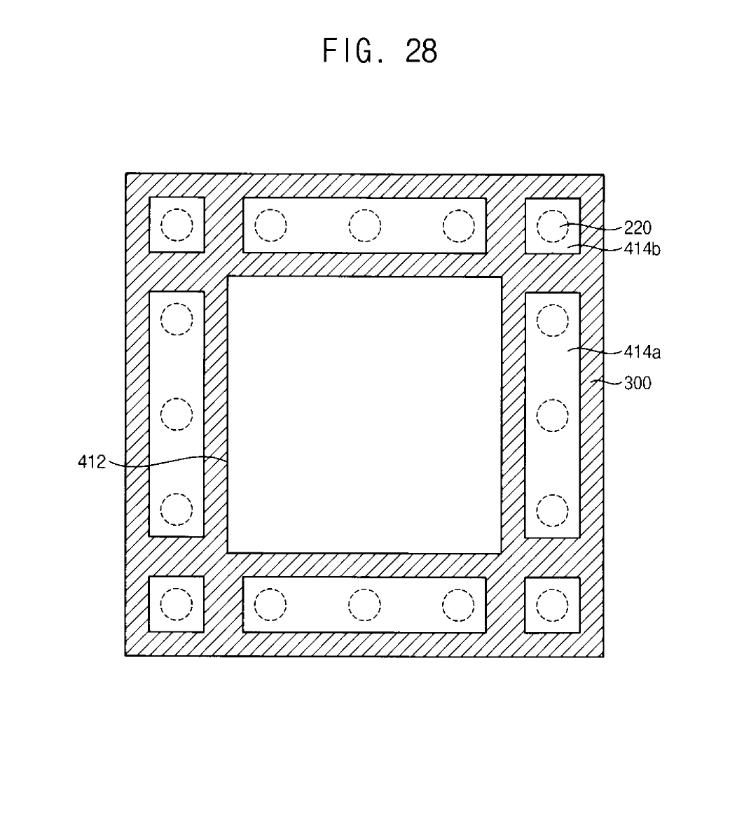

FIG. 28 is a plan view illustrating a second adhesive layer in accordance with an exemplary embodiment in accordance with principles of inventive concepts.

As illustrated in FIG. 28, the second adhesive layer may have a first adhesive layer pattern 414a covering three first conductive connection members 220 and a second adhesive layer pattern 414b covering one first conductive connection member 220.

Thus, the second adhesive layer may have a closed loop pattern or a spaced pattern. Alternatively, an EMI shield member 400 may be adhered to the first semiconductor chip 200 by a conductive layer. The conductive layer may be formed to cover the entire upper surfaces of the first semiconductor chip 200 and the first molding member 300.

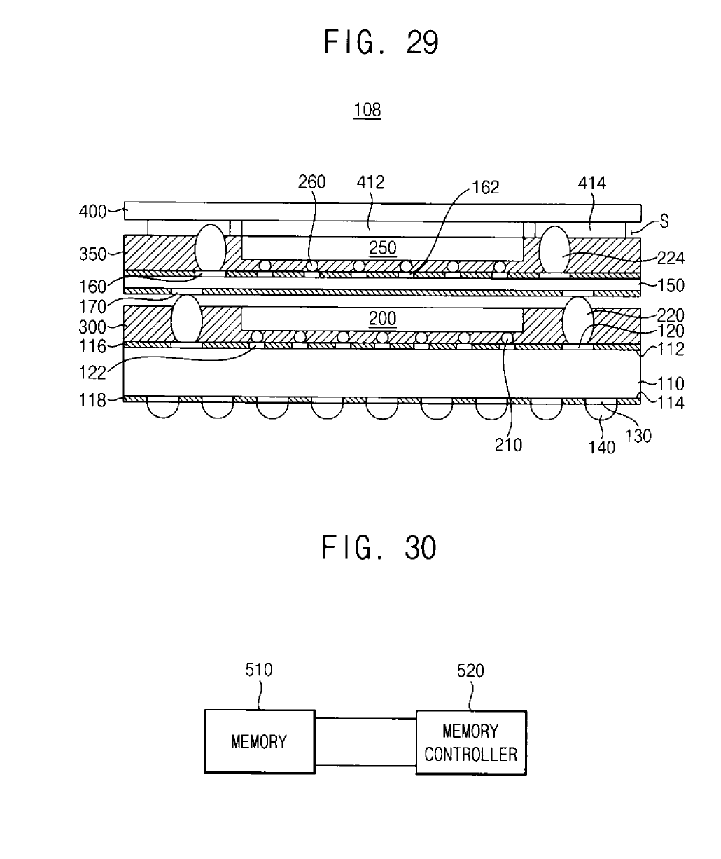

FIG. 29 is a cross-sectional view illustrating an exemplary embodiment of a semiconductor package in accordance with principles of inventive concepts. The semiconductor package may be substantially the same as or similar to that of FIG. 15, except for an addition of the conductive adhesive layer. Thus, like reference numerals refer to like elements, and, for brevity and clarity, detailed descriptions of those elements will not be repeated herein.

Referring to FIG. 29, the semiconductor package 108 may include a first package having a first semiconductor chip 200 and a second package stacked over the first package having a second semiconductor chip 250.

The first package may include a mounting substrate 110, the first semiconductor chip 200 mounted on the mounting substrate 110, a first molding member 300 covering at least a portion of the first semiconductor chip 200 and first conductive connection members 220 penetrating through the first molding member 300.

The second package may include a redistribution wiring substrate 150 stacked on the first molding member 300, the second semiconductor chip 250 mounted on a chip-mounting region, a second molding member 350 covering at least a portion of the second semiconductor chip 250, second conductive connection members 224 penetrating at least a portion of the second molding member 350 in a peripheral region of the redistribution wiring substrate 150 to protrude from the second molding member 350 and an EMI shield member 400 covering the first and the second semiconductor chips 200 and 250.

The second molding member 350 may be formed to leave exposed an upper surface of the second semiconductor chip 250. The second molding member 350 may be formed to leave exposed end portions of the second conductive connection members 224. For example, the second conductive connection members 224 may be solder balls. The end portions of the second conductive connection members 224 may protrude from an upper surface of the second molding member 350.

The EMI shield member 400 may be adhered to the exposed upper surface of the second semiconductor chip 250 by a first adhesive layer 412 and may be adhered to an upper surface of the second molding member 350 by a second adhesive layer 414. The first adhesive layer 412 may include a nonconductive TIM, and the second adhesive layer 414 may include a conductive TIM.

The second adhesive layer 414 may cover the second conductive connection members 224. The EMI shield member 400 may be electrically connected to the second conductive connection members 224 by the second adhesive layer 414.

FIG. 30 illustrates an exemplary embodiment in accordance with principles of inventive concepts that includes a memory 510 connected to a memory controller 520. The memory 510 may include a memory device in accordance with principles of inventive concepts. The memory controller 520 supplies input signals for controlling operation of the memory.

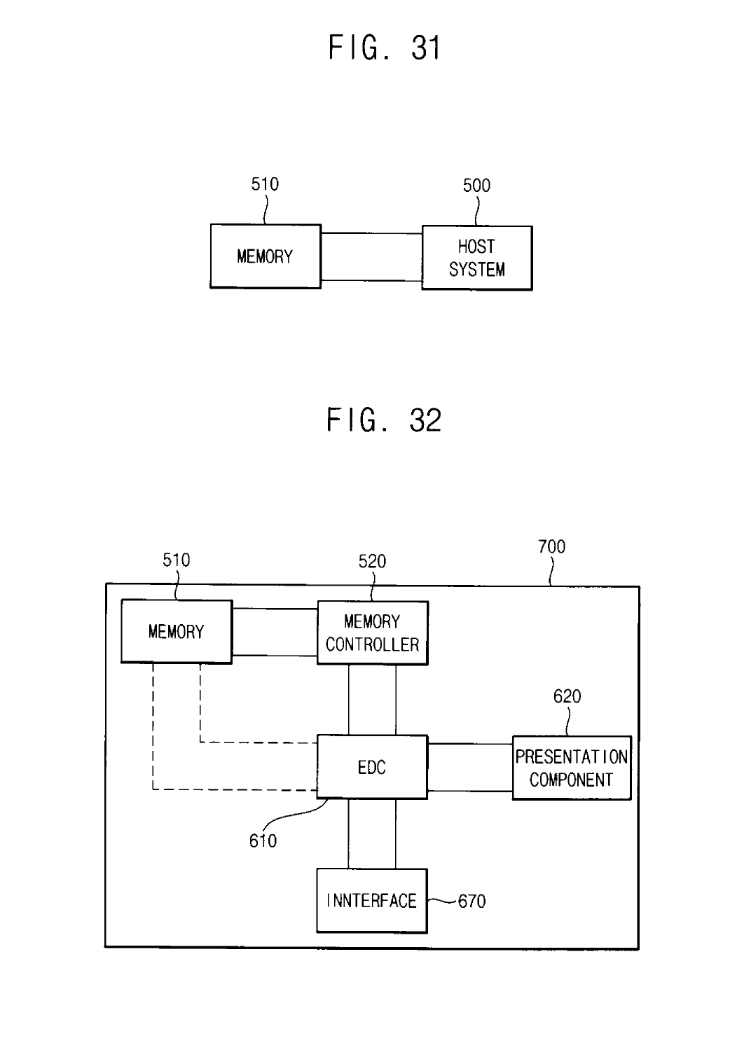

FIG. 31 illustrates an exemplary embodiment in accordance with principles of inventive concepts that includes a memory 510 connected with a host system 500. The memory 510 may include a memory device in accordance with principles of inventive concepts.

The host system 500 may include an electronic product such as a personal computer, digital camera, mobile application, game machine, or communication equipment, for example. The host system 500 supplies the input signals for controlling operation of the memory 510. The memory 510 may be used as a data storage medium.

FIG. 32 illustrates exemplary embodiment in accordance with principles of inventive concepts that includes a portable electronic device 700, which may be a wireless device. The portable electronic device 700 may be an MP3 player, video player, combination video and audio player, cellular telephone, tablet computer, or PDA, for example. As illustrated, the portable electronic device 700 may include memory 510 and memory controller 520. The memory 510 may include a memory device in accordance with principles of inventive concepts. The portable electronic device 700 may also include an encoder/decoder EDC 610, a presentation component 620 and an interface 670. Data (video, audio, for example.) is inputted/outputted to/from the memory 510 by the memory controller 520 by the EDC 610.

The foregoing is illustrative of exemplary embodiments and is not to be construed as limiting thereof. Although exemplary embodiments have been described, those skilled in the art will readily appreciate that many modifications are possible without materially departing from the novel teachings and advantages of inventive concepts.

What is claimed is:

1. A semiconductor package, comprising:
a mounting substrate having a chip-mounting region and a peripheral region;
a first semiconductor chip mounted on the chip-mounting region of the mounting substrate;
a first molding member covering at least a portion of the first semiconductor chip on the mounting substrate;
a plurality of first conductive connection members penetrating through at least a portion of the first molding member to protrude from the first molding member, the first conductive connection members electrically connected to a plurality of ground connection pads provided on the peripheral region of the mounting substrate, respectively; and
an electromagnetic interference (EMI) shield member disposed on an upper surface of the first molding member to cover the first semiconductor chip, the EMI shield member supported by the first conductive connection members and spaced apart from the first molding member.

2. The semiconductor package of claim 1, wherein the first molding member leaves exposed an upper surface of the first semiconductor chip.

3. The semiconductor package of claim 2, wherein the EMI shield member is adhered to the exposed upper surface of the first semiconductor chip by a thermally conductive adhesive layer.

4. The semiconductor package of claim 3, wherein the EMI shield member comprises a thermal interface material (TIM).

5. The semiconductor package of claim 2, wherein the first semiconductor chip is electrically connected to the mounting substrate by a plurality of bumps.

6. The semiconductor package of claim 1, wherein the first conductive connection member comprises a solder ball, and the solder ball is arranged on the ground connection pad.

7. The semiconductor package of claim 1, wherein the first conductive connection member comprises a conductive material, through-holes are formed through the first molding member to leave exposed the ground connection pads, and the conductive material fills the through-holes.

8. The semiconductor package of claim 1, wherein the EMI shield member comprises a graphite film or a copper film.

9. The semiconductor package of claim 1, wherein the EMI shield member covers at least a portion of an outer surface of the mounting substrate.

10. The semiconductor package of claim 1, further comprising a second semiconductor package having a second semiconductor chip mounted thereon, the first semiconductor package having a first semiconductor chip stacked on the second semiconductor package, and a mounting substrate of the second semiconductor package includes a redistribution wiring substrate.

11. A method of manufacturing a semiconductor package, comprising:
preparing a mounting substrate having a chip-mounting region and a peripheral region;
disposing a first semiconductor chip on the chip-mounting region of the mounting substrate;
forming a first molding member covering at least a portion of the first semiconductor chip on the mounting substrate and having first conductive connection members, the first conductive connection members penetrating through at least a portion of the first molding member to protrude from the first molding member and electrically connected to a plurality of ground connection pads formed on the peripheral region of the mounting substrate, respectively; and
disposing an EMI shield member on an upper surface of the first molding member to cover the first semiconductor chip, the EMI shield member supported by the first conductive connection members and spaced apart from the first molding member.

12. The method of claim 11, wherein forming the first molding member comprises:
arranging solder balls on the ground connection pads formed on the peripheral region of the mounting substrate, respectively; and
forming the first molding member to cover at least a portion of the first semiconductor chip on the mounting substrate and to leave exposed end portions of the solder balls.

13. The method of claim 11, wherein forming the first molding member comprises:
forming a first preliminary molding member to cover at least a portion of the first semiconductor chip on the mounting substrate;
forming through-holes in the first preliminary molding member to leave exposed the ground connection pads formed on the peripheral region of the mounting substrate; and
filling the through-holes with a conductive material.

14. The method of claim 11, wherein the first molding member is formed to leave exposed an upper surface of the first semiconductor chip.

15. The method of claim 14, wherein the EMI shield member is adhered to the exposed upper surface of the first semiconductor chip by a thermally conductive adhesive layer.

16. An electronic memory package, comprising:
a mounting substrate having a chip-mounting region and a peripheral region;
a first memory chip mounted on the chip-mounting region;
a first molding member covering at least a portion of the first memory chip on the mounting substrate;
a plurality of first conductive connection members penetrating through at least a portion of the first molding member to protrude from the first molding member, the first conductive connection members electrically connected to a plurality of ground connection pads provided on the peripheral region of the mounting substrate; and an electromagnetic interference (EMI) shield member disposed on an upper surface of the first molding member to cover the first memory chip, the EMI shield member supported by the first conductive connection members and spaced apart from the first molding member.

17. The electronic memory package of claim 16 further comprising a second memory package having a second semiconductor chip mounted thereon, the first memory package having a first semiconductor chip stacked on the second memory package, and a mounting substrate of the second memory package includes a redistribution wiring substrate.

18. The electronic memory package of claim 16, wherein the EMI shield member includes graphite or copper.

19. An electronic memory system including a memory package of claim 16 and a memory controller.

20. A wireless electronic device including an electronic memory system of claim 19.
